(19) United States
(12) Patent Application Publication
(10) Pub. No.: US 2025/0311568 A1
(43) Pub. Date: Oct. 2, 2025

(54) DISPLAY DEVICE

(71) Applicant: Samsung Display Co., Ltd., Yongin-Si (KR)

(72) Inventors: SUNKWUN SON, Yongin-si (KR); DONG HEE SHIN, Yongin-si (KR)

(21) Appl. No.: 18/979,601

(22) Filed: Dec. 13, 2024

(30) Foreign Application Priority Data
Apr. 1, 2024 (KR) 10-2024-0044016

(51) Int. Cl. H10K 59/131; H10K 59/122; H10K 59/126; H10K 59/60; H10K 59/88; H10K 102/10

(52) U.S. Cl. CPC H10K 59/131; H10K 59/122; H10K 59/126; H10K 59/60; H10K 59/88; H10K 2102/101

(57) ABSTRACT

Disclosed is a display device which includes a light emitting element, a light sensing element, a pixel defining layer in which a first opening exposing a first electrode of the light emitting element, a second opening exposing a first-first electrode of the light sensing element, and a third opening exposing a contact hole are defined, a dummy electrode that overlaps a partial area of the contact hole, and an insulating pattern that is disposed in the third opening and that overlaps the dummy electrode. A second electrode of the light emitting element and a second-first electrode of the light sensing element are different portions of a common electrode, and a contact portion connecting the common electrode to the shielding electrode is disposed in the contact hole.

### CROSS-REFERENCE TO RELATED APPLICATIONS

This application claims priority under 35 U.S.C. § 119 to Korean Patent Application No. 10-2024-0044016 filed on Apr. 1, 2024, in the Korean Intellectual Property Office, the disclosures of which are incorporated by reference herein in their entireties.

### BACKGROUND

Embodiments of the present disclosure described herein relate to a display device, and more particularly, relate to a display device including a light sensing element.

Electronic devices, such as a smart phone, a digital camera, a notebook computer, a car navigation unit, a smart television, and the like, which provide an image to a user include a display device for displaying an image. The display device includes a display panel for generating an image, an input device such as an input sensor, a camera for taking an external image, and various sensors.

The input sensor is disposed on the display panel and senses a touch of the user. The sensors may include a fingerprint sensor, a proximity sensor, an illuminance sensor, and the like. Among the sensors, the fingerprint sensor senses the user′s fingerprint provided on the display panel.

### SUMMARY

Embodiments of the present disclosure provide a display device for improving the sensitivity of a light sensor and preventing a voltage drop.

According to an embodiment, a display device includes a base layer, a readout line disposed on the base layer, a first insulating layer disposed on the readout line, a shielding electrode that is disposed on the first insulating layer and that overlaps the readout line, a second insulating layer that is disposed on the first insulating layer and that overlaps the shielding electrode and has a contact hole defined therein to expose a contact portion of the shielding electrode, a light emitting element that is disposed on the second insulating layer and that includes a first electrode, a second electrode disposed over the first electrode, and an emissive layer disposed between the first electrode and the second electrode, a light sensing element that is disposed on the second insulating layer and that includes a first-first electrode, a second-first electrode disposed over the first-first electrode, and a photoelectric conversion layer disposed between the first-first electrode and the second-first electrode, a pixel defining layer that is disposed on the second insulating layer and in which a first opening exposing the first electrode, a second opening exposing the first-first electrode, and a third opening exposes the contact hole are defined, a dummy electrode that is disposed on the second insulating layer and that overlaps a partial area of the contact hole, and an insulating pattern that is disposed in the third opening and that overlaps the dummy electrode. The second electrode and the second-first electrode are different portions of a common electrode and a contact portion of the common electrode connecting the common electrode to the contact portion of the shielding electrode is disposed in the contact hole.

An inner surface of the second insulating layer defines the contact hole overlaps the dummy electrode, and a portion of the dummy electrode overlapping the contact hole is spaced apart from a portion of the inner surface of the second insulating layer.

The display device may further include an organic layer disposed under the common electrode. A contact portion of the organic layer may be disposed in the contact hole. The contact portion of the organic layer may not completely cover the shielding electrode exposed by the contact hole.

The organic layer may overlap the emissive layer, the photoelectric conversion layer, and an upper surface of the pixel defining layer.

The display device may further include a signal line that is disposed under the first insulating layer and that receives a same driving voltage as the second electrode. The shielding electrode may be electrically connected to the signal line.

The signal line may extend in a first direction, and the shielding electrode may include a first extending portion that extends in the first direction and second extending portions that extend from the first extending portion in a second direction crossing the first direction.

The shielding electrode may include transparent conductive oxide.

The dummy electrode may include a same material as the first electrode.

The shielding electrode and the readout line may overlap the first electrode in a plane view.

A portion of the second insulating layer that in the third opening may have a smaller thickness than a portion of the second insulating layer that overlaps the pixel defining layer.

The display device may further include a first driving circuit that is disposed on the base layer and that controls the light emitting element and a second driving circuit disposed on the base layer and electrically connected to the light sensing element.

The readout line may be electrically connected to the second driving circuit.

The readout line may include a first portion and a second portion disposed on different layers.

The third opening may have a larger area than the contact hole in a plane view.

According to an embodiment, a display device includes a base layer, a driving circuit disposed on the base layer, a readout line disposed on the base layer and electrically connected to the driving circuit, a first insulating layer disposed on the readout line, a shielding electrode that is disposed on the first insulating layer and that overlaps the readout line, a second insulating layer that is disposed on the first insulating layer and that overlaps the shielding electrode and has a contact hole defined therein to expose a contact portion of the shielding electrode, a light sensing element that is disposed on the second insulating layer and that includes a first-first electrode, a second-first electrode disposed over the first-first electrode, and a photoelectric conversion layer disposed between the first-first electrode and the second-first electrode, a pixel defining layer that is disposed on the second insulating layer, the pixel defining layer having a first opening and a second opening defined therein, wherein the first opening exposing the first-first electrode and the second opening exposes the contact hole, and a dummy electrode that is disposed between the second insulating layer and the pixel defining layer and that overlaps a partial area of the contact hole. The second-first electrode is disposed on an upper surface of the pixel defining layer, and a contact portion connecting the second-first electrode to the shielding electrode is disposed in the contact hole.

An inner surface of the second insulating layer defines the contact hole overlaps the dummy electrode, and a portion of the dummy electrode overlapping the contact hole is spaced apart from a portion of the inner surface of the second insulating layer.

The display device may further include an organic layer that is disposed under the second-first electrode and that overlaps the upper surface of the pixel defining layer.

A contact portion of the organic layer may be disposed in the contact hole. The contact portion of the organic layer may not completely cover the contact portion exposed by the contact hole.

The display device may further include a signal line that is disposed under the first insulating layer and that receives a same driving voltage as the second electrode. The shielding electrode may be electrically connected to the signal line.

The shielding electrode may include transparent conductive oxide.

The dummy electrode may include a same material as the first-first electrode.

A portion of the second insulating layer that is disposed in the second opening may have a smaller thickness than a portion of the second insulating layer that overlaps the pixel defining layer.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2 is a sectional view of the display device illustrated in FIG. 1.

FIG. 3 is a sectional view of a display panel illustrated in FIG. 2.

FIG. 4 is a block diagram of the display device according to an embodiment of the present disclosure.

FIG. 5 is a view illustrating an equivalent circuit of one pixel among pixels illustrated in FIG. 4 and a light sensor adjacent to the one pixel.

FIG. 6 is a sectional view illustrating a light emitting element, a first transistor, a fourth transistor, and a sixth transistor of the pixel illustrated in FIG. 5.

FIG. 7 is a sectional view illustrating a light sensing element, a first sensing transistor, and a second sensing transistor of the light sensor illustrated in FIG. 5.

FIG. 8 is a view illustrating a planar arrangement of light emitting elements and light sensing elements disposed in a partial area of a display area illustrated in FIG. 4.

FIG. 9 is a schematic view illustrating a process of securing fingerprint information, which is biometric information, through light sensors SN illustrated in FIGS. 5 and 7.

FIG. 10 is a plan view illustrating a connection state of data lines and vertical and horizontal lines.

FIG. 11 is a plan view illustrating a connection state of readout lines and the vertical and horizontal lines.

FIGS. 12A, 12B, 12C, 12D, 12E, 12F, 12G, 12H, 121, 12J, 12K, 12L and 12M are plan views illustrating a stacked structure of pixels and light sensors.

FIG. 13 is a sectional view of the display panel corresponding to line I-I′ in FIG. 12M.

FIGS. 14A, 14B, 14C, 14D, 14E, 14F and 14G are sectional views illustrating a process of manufacturing the display panel.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

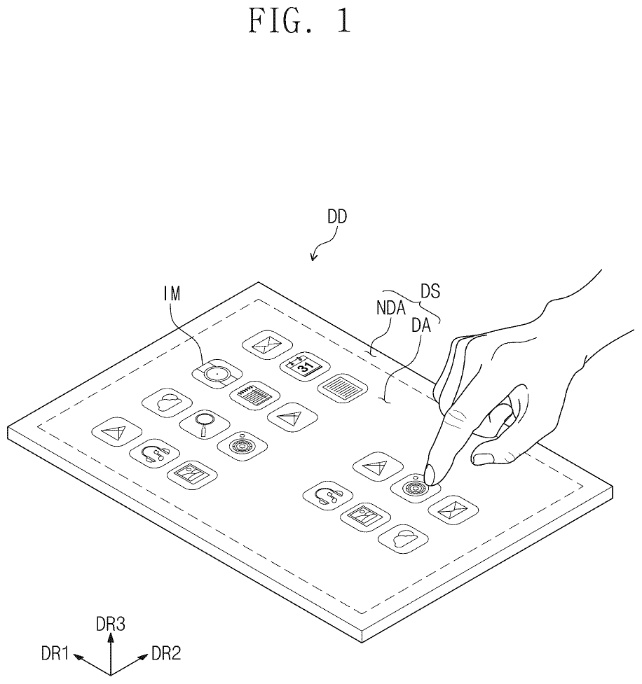

FIG. 1 is a perspective view of a display device DD according to an embodiment of the present disclosure.

Referring to FIG. 1, the display device DD according to an embodiment of the present disclosure may have a rectangular shape with long sides extending in a first direction DR1 and short sides extending in a second direction DR2 crossing the first direction DR1. However, without being limited thereto, the display device DD may have various shapes such as a circular shape, a polygonal shape, or the like. Hereinafter, a direction substantially perpendicular to a plane defined by the first direction DR1 and the second direction DR2 is defined as a third direction DR3. The expression “when viewed from above the plane” and “a plan view” used herein may mean that it is viewed in the third direction DR3.

The upper surface of the display device DD may be defined as a display surface DS and may have a plane defined by the first direction DR1 and the second direction DR2. Images IM generated by the display device DD may be provided to a user through the display surface DS.

The display device DD according to an embodiment of the present disclosure can be included in various electronic devices. The electronic device may further include a processor for controlling the display device DD and a housing for accommodating the display device DD. The display device DD may be included in various electronic devices, such as a smartphone, a tablet PC, a laptop, a TV, and a desk monitor.

The display surface DS may include a display area DA and a non-display area NDA around the display area DA. The display area DA displays an image, and the non-display area NDA does not display an image. The non-display area NDA may surround the display area DA. However, without being limited thereto, the non-display area NDA may not be disposed on one side of the display area DA.

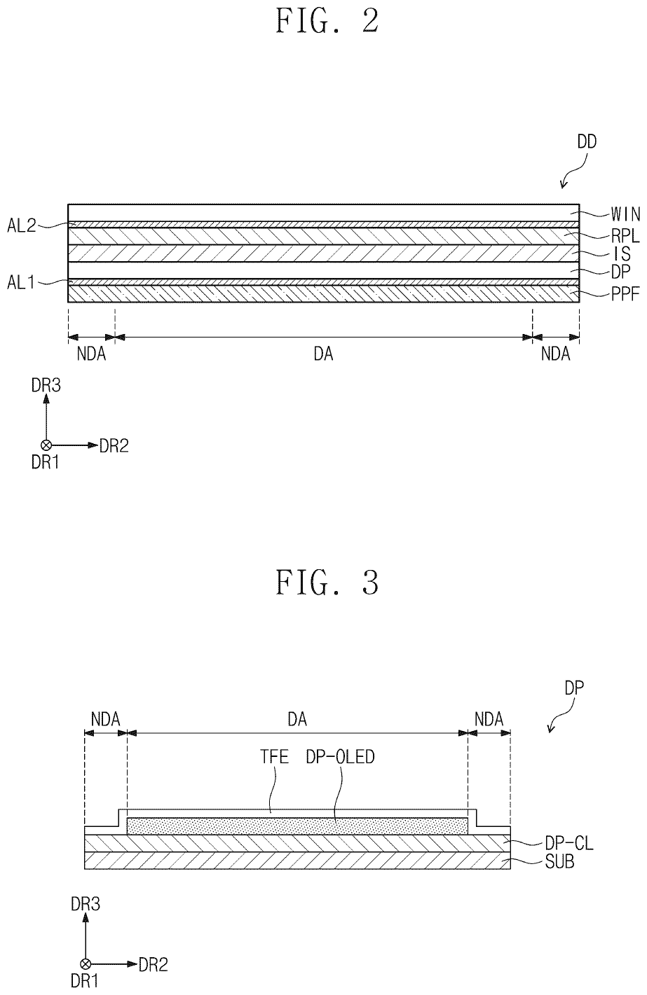

FIG. 2 illustrates a section of the display device DD illustrated in FIG. 1.

Referring to FIG. 2, the display device DD may include a display panel DP, an input sensor ISP, an anti-reflective layer RPL, a window WIN, a panel protection film PPF, and first and second adhesive layers ALI and AL2. In an embodiment of the present disclosure, the input sensor ISP may be omitted.

The display panel DP according to an embodiment of the present disclosure may be an emissive display panel, but the configuration of the display panel DP is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and quantum rods. Hereinafter, it will be exemplified that the display panel DP is an organic light emitting display panel.

The input sensor ISP may be disposed on the display panel DP. The input sensor ISP may include a plurality of sensors (not illustrated) for sensing an external input in a capacitive type. The input sensor ISP may be directly formed on the display panel DP when the display device DD is manufactured. However, without being limited thereto, the input sensor ISP may be manufactured as a panel separate from the display panel DP and may be attached to the display panel DP by an adhesive layer.

The anti-reflective layer RPL may be disposed on the input sensor ISP. The anti-reflective layer RPL may be directly formed on the input sensor ISP when the display device DD is manufactured. The anti-reflective layer RPL may include color filters and may further include a black matrix.

However, without being limited thereto, the anti-reflective layer RPL may be manufactured as a separate panel and may be attached to the input sensor ISP by an adhesive layer. The anti-reflective layer RPL may include an optical film such as a polarizer film. The anti-reflective layer RPL may decrease the reflectance of external light incident toward the display panel DP from above the display device DD. The external light may not be visible to the user due to the anti-reflective layer RPL.

The window WIN may be disposed on the anti-reflective layer RPL. The window WIN may protect the display panel DP, the input sensor ISP, and the anti-reflective layer RPL from external scratches and impacts.

The panel protection film PPF may be disposed under the display panel DP. The panel protection film PPF may protect a lower portion of the display panel DP. The panel protection film PPF may include a flexible plastic material such as polyethylene terephthalate (PET).

FIG. 3 is a sectional view of the display panel DP illustrated in FIG. 2.

Referring to FIG. 3, the display panel DP may include a base layer SUB, a circuit element layer DP-CL disposed on the base layer SUB, a display element layer DP-OLED disposed on the circuit element layer DP-CL, and a thin film encapsulation layer TFE disposed on the display element layer DP-OLED.

The base layer SUB may include a display area DA and a non-display area NDA around the display area DA, like the display device DD of FIG. 1. The base layer SUB may include a flexible plastic material, such as polyimide (PI), or glass.

The circuit element layer DP-CL may include a driving circuit of a light emitting element and a driving circuit of a light sensing element. The display element layer DP-OLED may include the light emitting element and the light sensing element. The thin film encapsulation layer TFE may be disposed on the circuit element layer DP-CL to cover the display element layer DP-OLED. The thin film encapsulation layer TFE may protect pixels from moisture, oxygen, and external foreign matter.

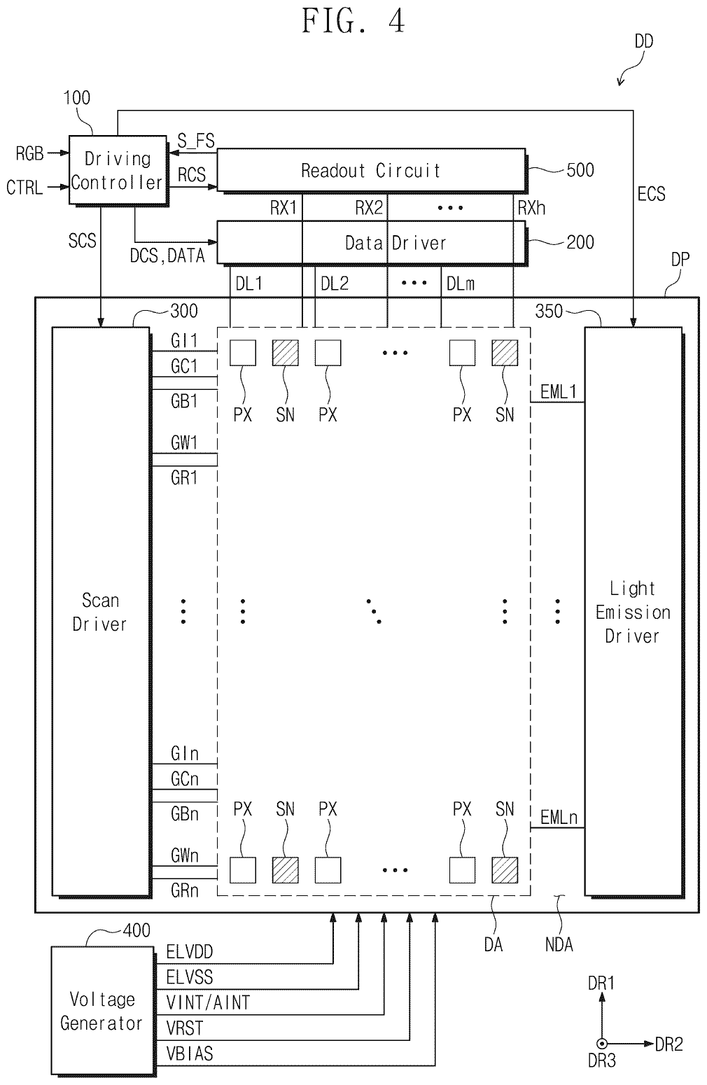

FIG. 4 is a block diagram of the display device DD according to an embodiment of the present disclosure.

Referring to FIG. 4, the display device DD includes the display panel DP, a driving controller 100, and a driving circuit of the display device. In an embodiment of the present disclosure, the driving circuit of the display device includes a data driver 200, a scan driver 300, a light emission driver 350, a voltage generator 400, and a readout circuit 500. In an embodiment of the present disclosure, the driving controller 100, the voltage generator 400 and the readout circuit 500 may be implemented as one driver IC.

The display panel DP may include a plurality of pixels PX disposed in the display area DA and a plurality of light sensors SN disposed in the display area DA. In an embodiment of the present disclosure, each of the plurality of light sensors SN may be disposed between two pixels PX disposed adjacent to each other. However, an arrangement between the light sensors SN and the pixels PX is not limited thereto.

The display panel DP may include initialization scan lines GI1 to GIn, compensation scan lines GC1 to GCn, bias scan lines GB1 to GBn, write scan lines GW1 to GWn, light emission control lines EML1 to EMLn, reset scan lines GR1 to GRn, data lines DL1 to DLm, and readout lines RL1 to RLh. The initialization scan lines GI1 to GIn, the compensation scan lines GC1 to GCn, the bias scan lines GB1 to GBn, the write scan lines GW1 to GWn, the light emission control lines EML1 to EMLn, and the reset scan lines GR1 to GRn extend in the second direction DR2. The data lines DL1 to DLm and the readout lines RL1 to RLh extend in the first direction DR1.

The plurality of pixels PX are electrically connected to the initialization scan lines GI1 to GIn, the compensation scan lines GC1 to GCn, the write scan lines GW1 to GWn, the bias scan lines GB1 to GBn, the light emission control lines EML1 to EMLn, and the data lines DL1 to DLm. However, the number of signal lines connected to each of the pixels PX may be changed without being limited thereto.

The plurality of light sensors SN are electrically connected to the write scan lines GW1 to GWn, the reset scan lines GR1 to GRn, and the readout lines RX1 to RXh. The number of signal lines connected to each of the plurality of light sensors SN may be changed without being limited thereto.

The driving controller 100 receives an image signal RGB and a control signal CTRL. The driving controller 100 generates an image data signal DATA by converting the data format of the image signal RGB according to the specification of an interface with the data driver 200. The driving controller 100 outputs a first control signal SCS, a second control signal ECS, a third control signal DCS, and a fourth control signal RCS.

The data driver 200 receives the third control signal DCS and the image data signal DATA from the driving controller 100. The data driver 200 converts the image data signal DATA into data signals and outputs the data signals to the plurality of data lines DL1 to DLm that will be described below. The data signals are analog voltages corresponding to gray level values of the image data signal DATA.

The scan driver 300 receives the second control signal SCS from the driving controller 100. In response to the second control signal SCS, the scan driver 300 outputs initialization scan signals to the initialization scan lines GI1 to GIn and outputs compensation scan signals to the compensation scan lines GC1 to GCn. Furthermore, in response to the second control signal SCS, the scan driver 300 may output write scan signals to the write scan lines GW1 to GWn and may output black scan signals to the bias scan lines GB1 to GBn. In addition, in response to the second control signal SCS, the scan driver 300 may output reset scan signals to the reset scan lines GR1 to GRn.

The light emission driver 350 receives the third control signal ECS from the driving controller 100. The light emission driver 350 may output light emission control signals to the light emission control lines EML1 to EMLn in response to the third control signal ECS. Alternatively, the scan driver 300 may be connected to the light emission control lines EML1 to EMLn. In this case, the light emission driver 350 may be omitted, and the scan driver 300 may output the light emission control signals to the light emission control lines EML1 to EMLn.

The readout circuit 500 receives the fourth control signal RCS from the driving controller 100. In response to the fourth control signal RCS, the readout circuit 500 may receive sensing signals from the readout lines RX1 to RXh. The readout circuit 500 may process the sensing signals received from the readout lines RX1 to RXh and may provide processed sensing signals S_FS to the driving controller 100. The driving controller 100 may recognize biometric information based on the sensing signals S_FS.

The voltage generator 400 generates voltages required for an operation of the display panel DP. In this embodiment, the voltage generator 400 may generate a first driving voltage ELVDD, a second driving voltage ELVSS having a lower level than the first driving voltage ELVDD, a first initialization voltage VINT, a second initialization voltage AINT, a reset voltage VRST, and a bias voltage VBIAS.

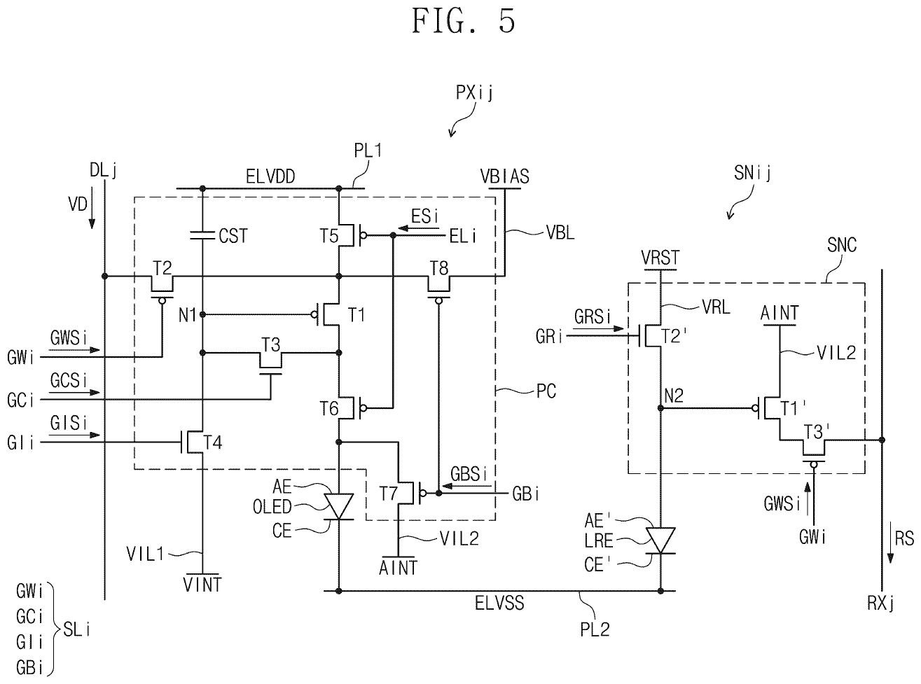

FIG. 5 is a view illustrating an equivalent circuit of one pixel PXij among the pixels PX illustrated in FIG. 4 and a light sensor SNij disposed adjacent to the one pixel PXij.

In FIG. 5, the pixel PXij connected to the i-th scan lines SLi, the i-th light emission line ELi, and the j-th data line DLj is illustrated as an example. In addition, the light sensor SNij connected to the i-th reset scan line GRi and the j-th readout line RXj is illustrated in FIG. 5. Here, “i” and “j” are natural numbers. The i-th scan lines SLi may include the i-th initialization scan line GIi, the i-th compensation scan line GCi, the i-th bias scan line GBi, and the i-th write scan line GWi.

Referring to FIG. 5, the pixel PXij may include a pixel driving circuit PC (or, a first driving circuit) and a light emitting element OLED electrically connected to the pixel driving circuit PC. The light emitting element OLED may be turned on or off under the control of the pixel driving circuit PC.

The pixel driving circuit PC may include a plurality of transistors T1 to T8 and a capacitor CST. The transistors T1 to T8 and the capacitor CST may control the amount of current flowing through the light emitting element OLED. The light emitting element OLED may generate light having a certain luminance depending on the amount of current provided thereto.

The i-th write scan line GWi may receive the i-th write scan signal GWSi, and the i-th compensation scan line GCi may receive the i-th compensation scan signal GCSi. The i-th initialization scan line GIi may receive the i-th initialization scan signal GISi, and the i-th bias scan line GBi may receive the i-th bias scan signal GBSi. The i-th reset scan line GRi may receive the i-th reset scan signal GRSi. The i-th light emission line ELi may receive the i-th light emission signal ESi.

A first initialization line VIL1 may receive the first initialization voltage VINT, and a second initialization line VIL2 may receive the second initialization voltage AINT. A bias line VBL may receive the bias voltage VBIAS. A first power line PL1 may receive the first driving voltage ELVDD, and a second power line PL2 may receive the second driving voltage ELVSS. The light emitting element OLED may be connected to the second power line PL2. A reset line VRL may receive the reset voltage VRST.

Each of the transistors T1 to T8 may include a source (or, a source terminal), a drain (or, a drain terminal), and a gate (or, a gate terminal). Hereinafter, in FIG. 5, for convenience, one of the source and the drain is defined as a first electrode, and the other one of the source and the drain is defined as a second electrode. In addition, the gate is defined as a gate electrode or a control electrode.

The transistors T1 to T8 may include the first to eighth transistors T1 to T8. The first, second, and fifth to eighth transistors T1, T2, and T5 to T8 may be PMOS transistors. The third and fourth transistors T3 and T4 may be NMOS transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light emission control transistors. The eighth transistor T8 may be defined as a bias transistor.

The light emitting element OLED may include an organic light emitting diode. The light emitting element OLED may include a first electrode, a second electrode, and an emissive layer disposed between the first electrode and the second electrode. In this embodiment, for convenience of description, the first electrode is described as an anode AE, and the second electrode is described as a cathode CE. The anode AE may be electrically connected to the first power line PL1 through the sixth, first, and fifth transistors T6, T1, and T5. The cathode CE may be electrically connected to the second power line PL2.

The first transistor T1 may be disposed between the fifth transistor T5 and the sixth transistor T6 and may be connected to the fifth transistor T5 and the sixth transistor T6. The first transistor T1 may be connected to the first power line PL1 through the fifth transistor T5 and may be connected to the anode AE through the sixth transistor T6.

The first transistor T1 may include a first electrode connected to the first power line PL1 through the fifth transistor T5, a second electrode connected to the anode AE through the sixth transistor T6, and a gate electrode connected to a first node N1. The first electrode of the first transistor T1 may be connected to the fifth

transistor T5, and the second electrode of the first transistor T1 may be connected to the sixth transistor T6. The first transistor T1 may control the amount of current flowing through the light emitting element OLED depending on the voltage of the first node N1 connected to the gate electrode of the first transistor T1.

The second transistor T2 may be disposed between the first transistor T1 and the j-th data line DLj and may be connected to the first transistor T1 and the j-th data line DLj. The second transistor T2 may include a first electrode connected to the j-th data line DLj, a second electrode connected to the first electrode of the first transistor T1, and a gate electrode connected to the i-th write scan line GWi.

The second transistor T2 may be turned on in response to the i-th write scan signal GWSi applied through the i-th write scan line GWi and may electrically connect the j-th data line DLj and the first electrode of the first transistor T1. The second transistor T2 may perform a switching operation of providing a data voltage VD applied through the j-th data line DLj to the first electrode of the first transistor T1. The third transistor T3 may be connected to the second electrode of the first

transistor T1 and the first node N1. The third transistor T3 may include a first electrode connected to the second electrode of the first transistor T1, a second electrode connected to the first node N1, and a gate electrode connected to the i-th compensation scan line GCi.

The third transistor T3 may be turned on in response to the i-th compensation scan signal GCSi applied through the i-th compensation scan line GCi and may electrically connect the second electrode of the first transistor T1 and the gate electrode of the first transistor T1. When the third transistor T3 is turned on, the first transistor T1 may be connected in the form of a diode.

The fourth transistor T4 may be connected to the first node N1. The fourth transistor T4 may include a first electrode connected to the first node N1, a second electrode connected to the first initialization line VIL1, and a gate electrode connected to the i-th initialization scan line GIi. The fourth transistor T4 may be turned on in response to the i-th initialization scan signal GISi applied through the i-th initialization scan line GIi and may provide the first initialization voltage VINT applied through the first initialization line VIL1 to the first node N1.

The fifth transistor T5 may include a first electrode connected to the first power line PL1, a second electrode connected to the first electrode of the first transistor T1, and a gate electrode connected to the i-th light emission line ELi. The sixth transistor T6 may include a first electrode connected to the second electrode of the first transistor T1, a second electrode connected to the anode AE, and a gate electrode connected to the i-th light emission line ELi.

The fifth transistor T5 and the sixth transistor T6 may be turned on in response to the i-th light emission signal ESi applied through the i-th light emission line ELi. The first driving voltage ELVDD may be provided to the light emitting element OLED through the turned-on fifth transistor T5, the turned-on first transistor T1, and the turned-on six transistor T6, and a driving current may flow through the light emitting element OLED. Accordingly, the light emitting element OLED may emit light.

The seventh transistor T7 may include a first electrode connected to the anode AE, a second electrode connected to the second initialization line VIL2, and a gate electrode connected to the i-th bias scan line GBi. The seventh transistor T7 may be turned on in response to the i-th bias scan signal GBSi applied through the i-th bias scan line GBi and may provide the second initialization voltage AINT received through the second initialization line VIL2 to the anode AE of the light emitting element OLED.

In an embodiment of the present disclosure, the seventh transistor T7 may be omitted. In an embodiment of the present disclosure, the second initialization voltage AINT may have a level different from that of the first initialization voltage VINT. However, without being limited thereto, the second initialization voltage AINT may have the same level as the first initialization voltage VINT.

The seventh transistor T7 may improve the ability of the pixel PXij to express black. When the seventh transistor T7 is turned on, a parasitic capacitor of the light emitting element OLED may be discharged. Accordingly, when an image having black luminance is displayed, the light emitting element OLED does not emit light due to the leakage current of the first transistor T1, and thus the ability to express black may be improved.

The capacitor CST may include a first electrode connected to the first power line PL1 and a second electrode connected to the first node N1. When the fifth transistor T5 and the sixth transistor T6 are turned on, the amount of current flowing through the first transistor T1 may be determined depending on the voltage stored in the capacitor CST.

The eighth transistor T8 may include a first electrode connected to the bias line VBL, a second electrode connected to the first electrode of the first transistor T1, and a gate electrode connected to the i-th bias scan line GBi. In an embodiment of the present disclosure, the eighth transistor T8 may be omitted.

The eighth transistor T8 may be turned on in response to the i-th bias scan signal GBSi and may provide the bias voltage VBIAS to the first electrode of the first transistor T1. As the bias voltage VBIAS is applied to the first transistor T1, the movement of the hysteresis curve of the first transistor T1 may be suppressed.

The light sensor SNij may include a sensor driving circuit SNC (or, a second driving circuit) and a light sensing element LRE electrically connected to the sensor driving circuit SNC. The sensor driving circuit SNC may sense an electrical signal from the light sensing element LRE.

The sensor driving circuit SNC may include a first sensing transistor T1′, a second sensing transistor T2′, and a third sensing transistor T3′. The first and third sensing transistors T1′ and T3′ may be PMOS transistors, and the second sensing transistor T2′ may be an NMOS transistor.

The light sensing element LRE may be a photo diode. The light sensing element LRE may convert light energy incident from the outside into electrical signal. The light sensing element LRE may include a first electrode, a second electrode, and a photoelectric conversion layer disposed between the first electrode and the second electrode. In this embodiment, for convenience of description, the first electrode is described as an anode AE′, and the second electrode is described as a cathode CE′. The anode AE′ may be connected to a second node N2, and the cathode CE′ may be connected to the second power line PL2. Meanwhile, to distinguish the anode AE and the cathode CE of the light emitting element OLED from the anode AE′ and the cathode CE′ of the light sensing element LRE, the anode AE and the cathode CE of the light emitting element OLED may be defined as a first electrode and a second electrode, respectively, and the anode AE′ and the cathode CE′ of the light sensing element LRE may be defined as a first-first electrode and a second-first electrode, respectively.

The first sensing transistor T1′ may be connected to the light sensing element LRE, the second sensing transistor T2′, and the third sensing transistor T3′. The first sensing transistor T1′ may include a first electrode that receives the second initialization voltage AINT, a gate electrode connected to the second node N2, and a second electrode connected to the third sensing transistor T3′. The first electrode of the first sensing transistor T1′ may be connected to the second initialization line VIL2 to receive the second initialization voltage AINT. The second sensing transistor T2′ may include a first electrode connected to the second node N2, a gate electrode connected to the i-th reset scan line GRi, and a second electrode connected to the reset line VRL. The third sensing transistor T3′ may include a first electrode connected to the second electrode of the first sensing transistor T1′, a gate electrode connected to the i-th write scan line GWi, and a second electrode connected to the readout line RXj. The third sensing transistor T3′ may be turned on in response to the i-th write scan signal GWSi received through the i-th write scan line GWi.

The second sensing transistor T2′ may be turned on in response to the i-th reset scan signal GRSi received through the i-th reset scan line GRi. The turned-on second sensing transistor T2′ may receive the reset voltage VRST and may provide the reset voltage VRST to the second node N2. The second node N2 may be reset by the reset voltage VRST.

The i-th write scan signal GWSi may be applied to the gate electrode of the third sensing transistor T3′, and the third sensing transistor T3′ may be turned on accordingly. The first sensing transistor T1′ may be connected to the readout line RXj through the turned-on third sensing transistor T3′.

The light sensing element LRE may receive light and may convert the light into an electrical signal. At this time, the voltage of the second node N2 may change. When the first sensing transistor T1′ is turned on, the second initialization voltage AINT provided to the first sensing transistor T1′ may be controlled depending on a change in the voltage of the second node N2 and may be provided to the readout line RXj through the third sensing transistor T3′. Accordingly, a signal sensed by the light sensing element LRE may be output through the readout line RXj as a sensing signal RS.

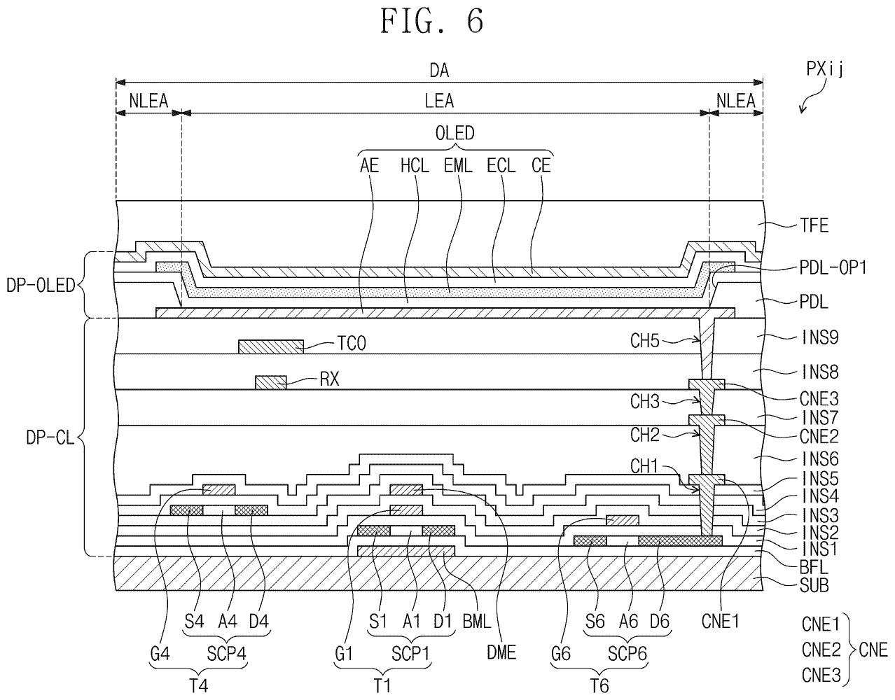

FIG. 6 is a sectional view illustrating the light emitting element OLED, the first transistor T1, the fourth transistor T4, and the sixth transistor T6 of the pixel PXij illustrated in FIG. 5.

In FIG. 6, the first, fourth, and sixth transistors T1, T4, and T6 of the pixel driving circuit PC illustrated in FIG. 5 are illustrated. Referring to FIG. 6, a shielding layer BML may be disposed on the base layer SUB. The shielding layer BML may overlap the first transistor T1. The shielding layer BML may include metal and may receive a constant voltage. When the constant voltage is applied to the shielding layer BML, the threshold voltage Vth of the first transistor T1 disposed over the shielding layer BML may remain unchanged.

In addition, the shielding layer BML may block light incident to the first transistor T1 from below the shielding layer BML. For example, the shielding layer BML may include reflective metal. In an embodiment of the present disclosure, the shielding layer BML may be omitted.

A buffer layer BFL may be disposed on the base layer SUB. The buffer layer BFL may include an inorganic layer. The buffer layer BFL may cover the shielding layer BML. A semiconductor layer SCP1 (or, a semiconductor pattern area, hereinafter, referred to as the first semiconductor layer) of the first transistor T1 and a semiconductor layer SCP6 (or, a semiconductor pattern area, hereinafter, referred to as the sixth semiconductor layer) of the sixth transistor T6 may be disposed on the buffer layer BFL. The first and sixth semiconductor layers SCP1 and SCP6 may include poly-silicon. However, without being limited thereto, the first and sixth semiconductor layers SCP1 and SCP6 may include amorphous silicon.

The first and sixth semiconductor layers SCP1 and SCP6 may be formed through a same process, and partial areas of the first and sixth semiconductor layers SCP1 and SCP6 may be doped with an N-type dopant or a P-type dopant. The first and sixth semiconductor layers SCP1 and SCP6 may each include highly-doped (or non-doped) areas and a lightly-doped area. The highly-doped areas have a higher conductivity than the lightly-doped area. The highly-doped areas may substantially correspond to the source and the drain of each of the first and sixth transistors T1 and T6. The lightly-doped area may substantially correspond to the active (or, channel) area of each of the first and sixth transistors T1 and T6.

The highly-doped areas of the first semiconductor layer SCP1 may include a first source area S1 and a first drain area D1. The lightly-doped area of the first semiconductor layer SCP1 is defined as a first channel area A1 and disposed between the first source area S1 and the first drain area D1. The sixth semiconductor layer SCP6 may include a sixth source area S6, a sixth channel area A6, and a sixth drain area D6.

Although the first semiconductor layer SCP1 and the sixth semiconductor layer SCP6 are spaced apart from each other on the cross-sectional view of FIG. 6, the first semiconductor layer SCP1 and the sixth semiconductor layer SCP6 may be connected to each other to form one body when viewed from above the plane. In other words, the first semiconductor layer SCP1 and the sixth semiconductor layer SCP6 may be different portions or areas of one semiconductor pattern.

A first insulating layer INS1 may be disposed on the buffer layer BFL to cover the first and sixth semiconductor layers SCP1 and SCP6. The gate electrodes of the first and sixth transistors T1 and T6 are disposed on the first insulating layer INS1. The gate electrodes of the first and sixth transistors T1 and T6 may be formed through a same process. Hereinafter, the gate electrode of the first transistor T1 is defined as a first gate electrode G1, and the gate electrode of the sixth transistor T6 is defined as a sixth gate electrode G6.

A second insulating layer INS2 may be disposed on the first insulating layer INS1 to cover the first and sixth gate electrodes G1 and G6. An additional electrode DME may be disposed on the second insulating layer INS2. The additional electrode DME may be disposed over the first gate electrode G1 and may overlap the first gate electrode G1 when viewed from above the plane. The additional electrode DME may form the above-described capacitor CST together with the first gate electrode G1. In other words, the first gate electrode G1 corresponds to one electrode of the capacitor CST, and the additional electrode DME corresponds to the other electrode of the capacitor CST.

A third insulating layer INS3 may be disposed on the second insulating layer INS2 to cover the additional electrode DME. A semiconductor layer SCP4 (or, a semiconductor pattern area, hereinafter, referred to as the fourth semiconductor layer) of the fourth transistor T4 may be disposed on the third insulating layer INS3. The fourth semiconductor layer SCP4 may include an oxide semiconductor including metal oxide. The oxide semiconductor may include a crystalline or amorphous oxide semiconductor.

The fourth semiconductor layer SCP4 may include a plurality of areas distinguished from one another depending on whether metal oxide is reduced or not. Areas where metal oxide is reduced (hereinafter, referred to as the reduced areas) have a higher conductivity than an area where metal oxide is not reduced (hereinafter, referred to as the non-reduced area). The reduced areas may substantially correspond to the source and the drain of the fourth transistor T4. The non-reduced area may substantially correspond to the active (or, channel) area of the fourth transistor T4.

The reduced areas of the fourth semiconductor layer SCP4 may include a fourth source area S4 and a fourth drain area D4. A fourth channel area A4 may be disposed between the fourth source area S4 and the fourth drain area D4.

A fourth insulating layer INS4 may be disposed on the third insulating layer INS3 to cover the fourth semiconductor layer SCP4. The fourth gate electrode G4 of the fourth transistor T4 may be disposed on the fourth insulating layer INS4.

A fifth insulating layer INS5 may be disposed on the fourth insulating layer INS4 to cover the fourth gate electrode G4. The buffer layer BFL and the first to fifth insulating layers INS1 to INS5 may include inorganic layers.

A connecting electrode CNE may be disposed between the sixth transistor T6 and the light emitting element OLED. The connecting electrode CNE may electrically connect the sixth transistor T6 and the light emitting element OLED. The connecting electrode CNE may include a first connecting electrode CNE1, a second connecting electrode CNE2 disposed over the first connecting electrode CNE1, and a third connecting electrode CNE3 disposed over the second connecting electrode CNE2.

The first connecting electrode CNE1 may be disposed on the fifth insulating layer INS5 and may be connected to the sixth drain area D6 through a first contact hole CH1 defined in the first to fifth insulating layers INS1 to INS5. A sixth insulating layer INS6 may be disposed on the fifth insulating layer INS5 to cover the first connecting electrode CNE1. The second connecting electrode CNE2 may be disposed on the sixth insulating layer INS6. The second connecting electrode CNE2 may be connected to the first connecting electrode CNE1 through a second contact hole CH2 defined in the sixth insulating layer INS6. A seventh insulating layer INS7 may be disposed on the sixth insulating layer INS6 to cover the second connecting electrode CNE2.

The third connecting electrode CNE3 may be disposed on the seventh insulating layer INS7. The third connecting electrode CNE3 may be connected to the second connecting electrode CNE2 through a third contact hole CH3 defined in the seventh insulating layer INS7. A readout line RX formed through a same process as the third connecting electrode CNE3 may be disposed on the seventh insulating layer INS7.

An eighth insulating layer INS8 may be disposed on the seventh insulating layer INS7 to cover the third connecting electrode CNE3 and the readout line RX. A shielding electrode TCO may be disposed on the eighth insulating layer INS8. The shielding electrode TCO may overlap (e. g. completely cover) the readout line RX in a plan view and may overlap a first electrode AE that will be described below. The shielding electrode TCO may shield coupling between the readout line RX and the first electrode AE. The shielding electrode TCO may shield noise that interferes with the readout line RX.

A ninth insulating layer INS9 may be disposed on the eighth insulating layer INS8 to cover the shielding electrode TCO. The sixth to ninth insulating layers INS6 to INS9 may include an inorganic layer or an organic layer. In this embodiment, each of the sixth to ninth insulating layers INS6 to INS9 may include an organic layer.

The light emitting element OLED is disposed on the ninth insulating layer INS9. The light emitting element OLED may include the first electrode AE, a second electrode CE, a hole control layer HCL, an electron control layer ECL, and an emissive layer EML. The first electrode AE may be the anode AE illustrated in FIG. 5, and the second electrode CE may be the cathode CE illustrated in FIG. 5. The second electrode CE may be disposed over the first electrode AE. The hole control layer HCL and the electron control layer ECL may be disposed between the first electrode AE and the second electrode CE. The emissive layer EML may be disposed between the hole control layer HCL and the electron control layer ECL.

The display area DA may include an emissive area LEA corresponding to the light emitting element OLED and a non-emissive area NLEA disposed adjacent to the emissive area LEA. The first electrode AE may be disposed on the ninth insulating layer INS9. The first electrode AE may be electrically connected to the third connecting electrode CNE3 through a fifth contact hole CH5 defined in the eighth insulating layer INS8 and the ninth insulating layer INS9.

A pixel defining layer PDL exposing a certain portion of the first electrode AE may be disposed on the first electrode AE and the ninth insulating layer INS9. A first opening PDL-OP1 for exposing the certain portion of the first electrode AE may be defined in the pixel defining layer PDL. The emissive area LEA corresponds to the first opening PDL-OP1.

The hole control layer HCL may be disposed on the first electrode AE and the pixel defining layer PDL. The hole control layer HCL may be commonly disposed in the emissive area LEA and the non-emissive area NLEA. The hole control layer HCL may include a hole transport layer and a hole injection layer.

The emissive layer EML may be disposed on the hole control layer HCL. The emissive layer EML may be disposed in an area corresponding to the first opening PDL-OP1. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may be commonly disposed in the emissive area LEA and the non-emissive area NLEA. The electron control layer ECL may include an electron transport layer and an electron injection layer.

The second electrode CE may be disposed on the electron control layer ECL. The second electrode CE may be commonly disposed for the pixels PX. That is, the second electrode CE may be commonly disposed over the emissive layers EML of the pixels PX.

The layers from the buffer layer BFL to the ninth insulating layer INS9 may be defined as the circuit element layer DP-CL. The layer in which the light emitting element OLED is disposed may be defined as the display element layer DP-OLED.

The thin film encapsulation layer TFE may be disposed on the light emitting element OLED. The thin film encapsulation layer TFE may include an inorganic layer, an organic layer, and an inorganic layer that are sequentially stacked one above another.

The inorganic layers may include an inorganic material and may protect the pixels from moisture/oxygen. The organic layer may include an organic material and may protect the pixels PX from foreign matter such as dust particles.

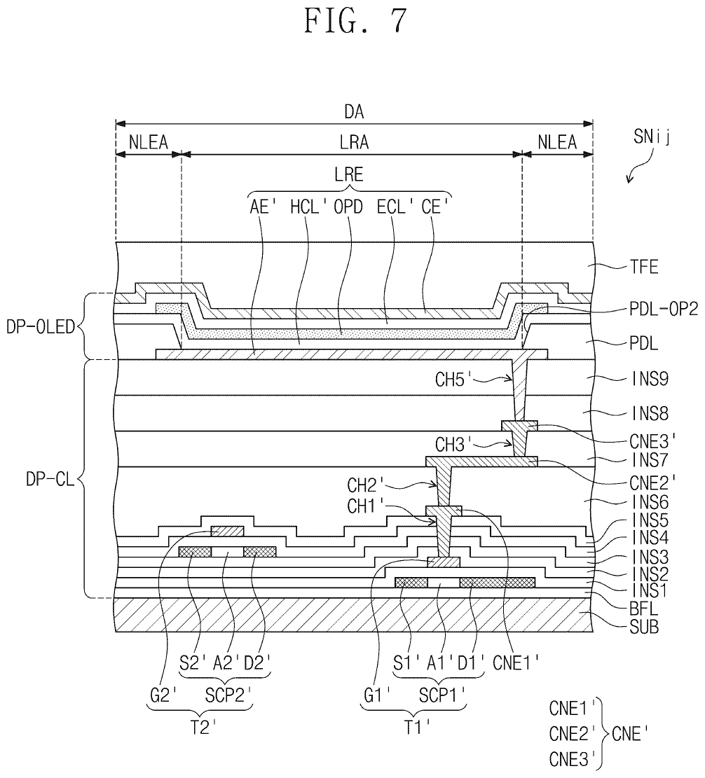

FIG. 7 is a sectional view illustrating the light sensing element LRE, the first sensing transistor T1′, and the second sensing transistor T2′ of the light sensor SNij illustrated in FIG. 5. Detailed description of components identical to the components described above with reference to FIG. 6 may be referred to by the above description in relation to FIG. 6.

A semiconductor layer SCP1′ (hereinafter, referred to as the first sensing semiconductor layer) of the first sensing transistor T1′ may be formed through a same process as the first semiconductor layer SCP1 of FIG. 6, and a semiconductor layer SCP2′ (hereinafter, referred to as the second sensing semiconductor layer) of the second sensing transistor T2′ may be formed through a same process as the fourth semiconductor layer SCP4 of FIG. 6. The first sensing semiconductor layer SCP1′ may include a first source area S1′, a first drain area DI′, and a first channel area A1′. The second sensing semiconductor layer SCP2′ may include a second source area S2′, a second drain area D2′, and a second channel area A2′.

A stacked structure of the first sensing transistor T1′ may be substantially the same as the stacked structure of the first transistor T1 illustrated in FIG. 6. A stacked structure of the second sensing transistor T2′ may be substantially the same as the stacked structure of the fourth transistor T4 illustrated in FIG. 6. Although not illustrated, a stacked structure of the third sensing transistor T3′ may be substantially the same as the stacked structure of the first sensing transistor T1′.

A connecting electrode CNE′ may include a first connecting electrode CNE1′(or, a first sensing connecting electrode), a second connecting electrode CNE2′ (or, a second sensing connecting electrode), and a third connecting electrode CNE3′ (or, a third sensing connecting electrode). The first connecting electrode CNE1′ may be disposed on the same layer as the first connecting electrode CNE1 illustrated in FIG. 6 and may be connected to a first gate electrode G1′ of the first sensing transistor T1′ through a first contact hole CH1′. Hereinafter, the first gate electrode G1′ is defined as a first sensing gate electrode G1′ to distinguish from the above-described first gate electrode G1.

The second connecting electrode CNE2′ may be disposed on the same layer as the second connecting electrode CNE2 illustrated in FIG. 6 and may be connected to the first connecting electrode CNE1′ through a second contact hole CH2′ defined in the sixth insulating layer INS6. The third connecting electrode CNE3′ may be disposed on the same layer as the third connecting electrode CNE3 illustrated in FIG. 6 and may be connected to the second connecting electrode CNE2′ through a third contact hole CH3′. A first electrode AE′ may be connected to the third connecting electrode CNE3′ through a fifth contact hole CH5′ defined in the eighth insulating layer INS8 and the ninth insulating layer INS9.

Referring to FIG. 7, the display area DA may include a light receiving area LRA corresponding to the light sensor SNij and a non-emissive area NLEA disposed adjacent to the light receiving area LRA. The non-emissive area NLEA may be the non-emissive area NLEA illustrated in FIG. 6.

The light sensing element LRE may include the first electrode AE′, a second electrode CE′, a hole control layer HCL′, an electron control layer ECL′, and a photoelectric conversion layer OPD. The first electrode AE′ may be the anode AE′ illustrated in FIG. 5, and the second electrode CE′ may be the cathode CE′ illustrated in FIG. 5. A second opening PDL-OP2 for exposing a certain portion of the first electrode AE′ may be defined in the pixel defining layer PDL. The light receiving area LRA corresponds to the second opening PDL-OP2.

The first electrode AE′ is formed through the same process as the first electrode AE illustrated in FIG. 6. The second electrode CE′ may be connected to the second electrode CE illustrated in FIG. 6 to form one-body, the hole control layer HCL′ may be connected to the hole control layer HCL illustrated in FIG. 6 to form one-body, and the electron control layer ECL′ may be connected to the electron control layer ECL illustrated in FIG. 6 to form one-body. The second electrode CE′ of FIG. 7 and the second electrode CE of FIG. 6 may be different areas of a common electrode. The common electrode may be deposited through an open mask to have a one-body shape. The hole control layer HCL′ of FIG. 7 and the hole control layer of FIG. 6 may be different areas of a common hole control layer, and the electron control layer ECL′ of FIG. 7 and the electron control layer of FIG. 6 may be different areas of a common electron control layer.

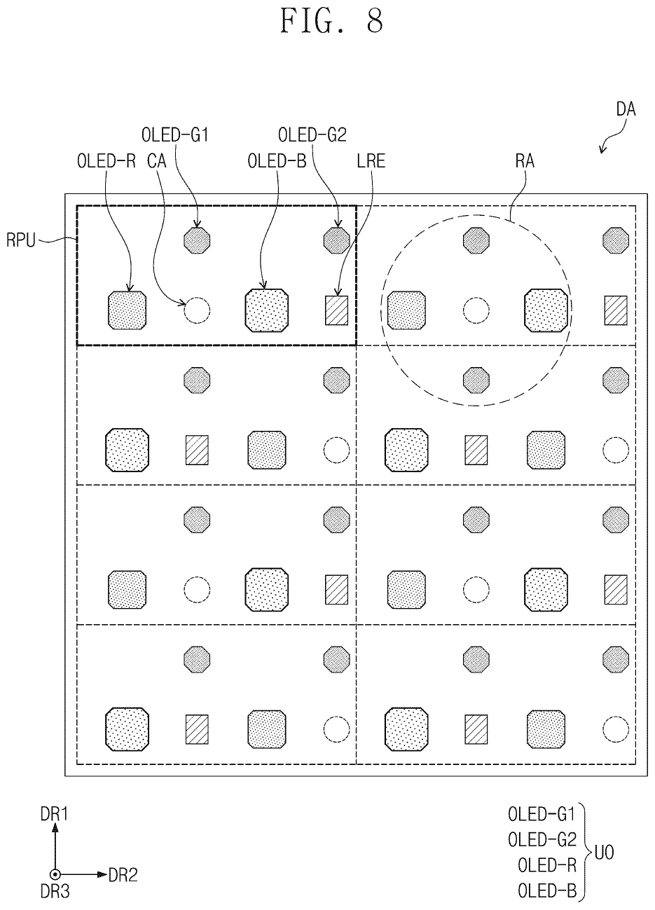

FIG. 8 is a view illustrating a planar arrangement of light emitting elements OLED and light sensing elements LRE disposed in a partial area of the display area DA illustrated in FIG. 4.

In FIG. 8, unit areas RPU repeatedly arranged in the display area DA are illustrated. A unit light emitting element UO and at least one light sensing element LRE are disposed in each of the unit areas RPU. In this embodiment, the unit light emitting element UO may include a first light emitting element OLED-R, a second-first light emitting element OLED-G1, a second-second light emitting element OLED-G2, and a third light emitting element OLED-B. The first light emitting element OLED-R generates light of a first color, for example, red light. The second-first light emitting element OLED-G1 and the second-second light emitting element OLED-G2 generate light of a second color, for example, green light. The third light emitting element OLED-B generates light of a third color, for example, blue light. The third light emitting element OLED-B may have the largest light emitting area, and the second-first light emitting element OLED-G1 and the second-second light emitting element OLED-G2 may have the smallest light emitting area.

A contact area CA may be located in each of the unit areas RPU. The contact area CA may be an area where the common electrode is connected with the shielding electrode TCO (refer to FIG. 6) disposed under the common electrode, and the common electrode may be an electrode that includes the second electrode CE of FIG. 6 and the second electrode CE′ of FIG. 7. Detailed description thereabout will be given below.

The arrangement of the light emitting elements OLED-R, OLED-G1, OLED-G2, and OLED-B, the light sensing element LRE, and the contact area CA in the unit areas RPU may be the same.

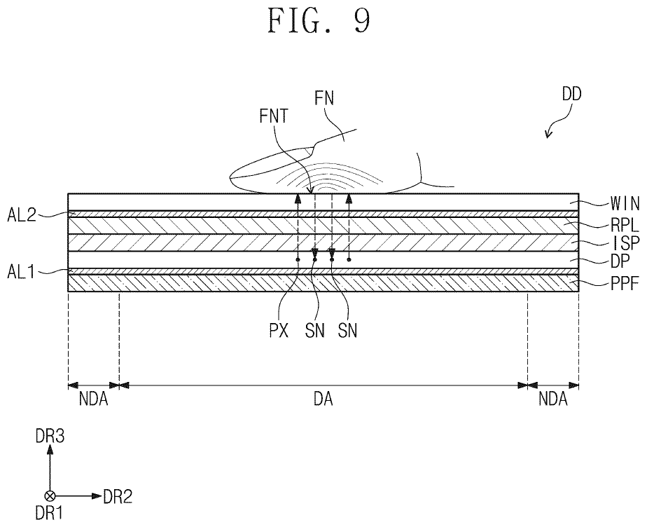

FIG. 9 is a schematic view illustrating a process of securing fingerprint information, which is biometric information, through the light sensors SNij illustrated in FIGS. 5 and 7.

Referring to FIG. 9, the display device DD may include the plurality of light sensors SN. Each of the light sensors SN may have the same configuration as the light sensor SNij illustrated in FIGS. 5 and 7. The light sensors SN may sense a fingerprint FNT of a finger FN on the display panel DP. Light generated from the light emitting elements OLED of the pixels PX may be provided to the fingerprint FNT and may be reflected from the fingerprint FNT. The fingerprint FNT may be defined by the shapes of valleys and ridges, and the light reflectance at the valleys may be different from the light reflectance at the ridges. The plurality of light sensors SN receive light reflected from the valleys and/or ridges depending on their positions. Information on the fingerprint FNT may be obtained using information detected by the plurality of light sensors SN.

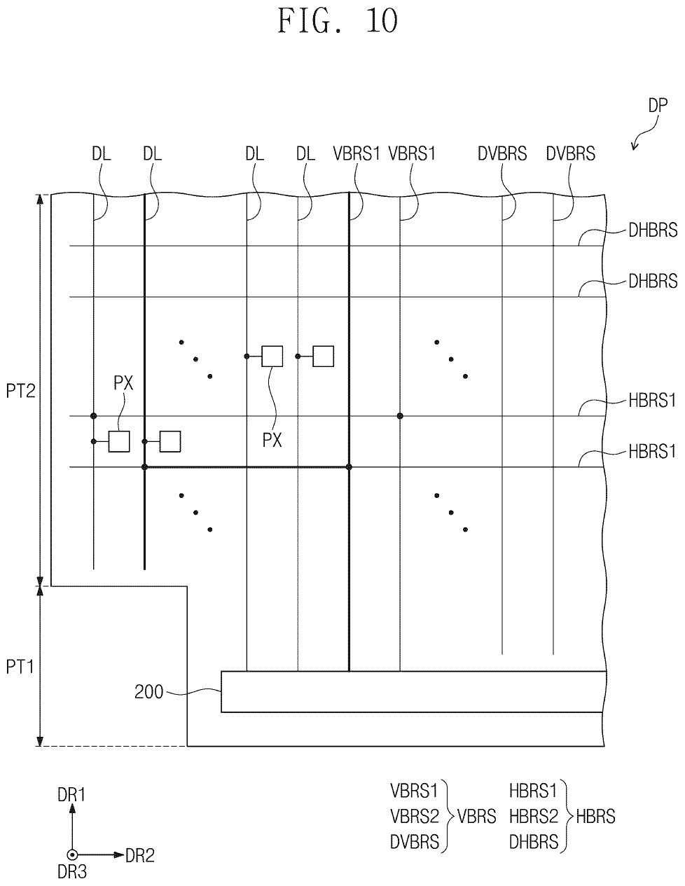

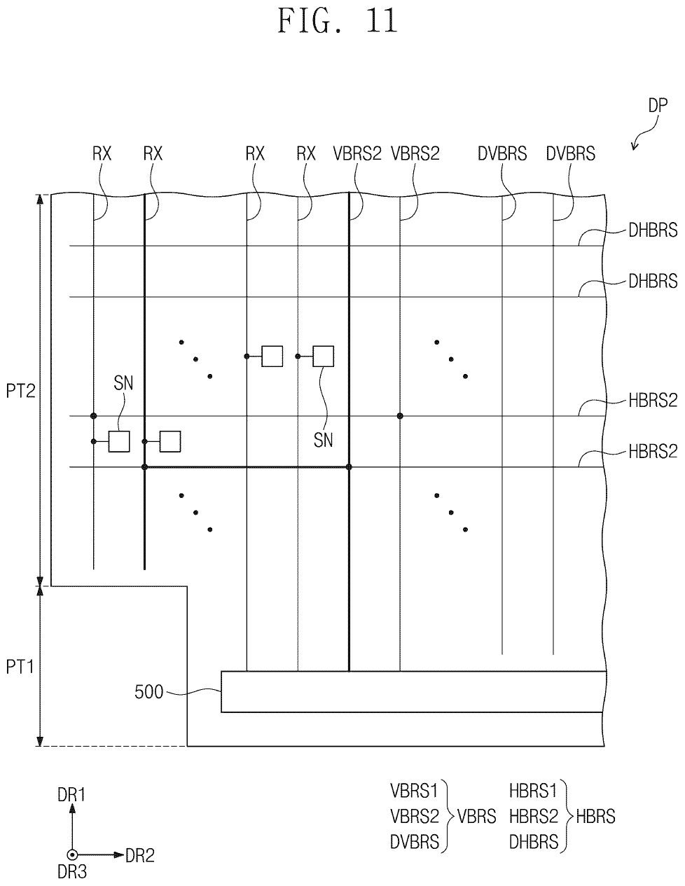

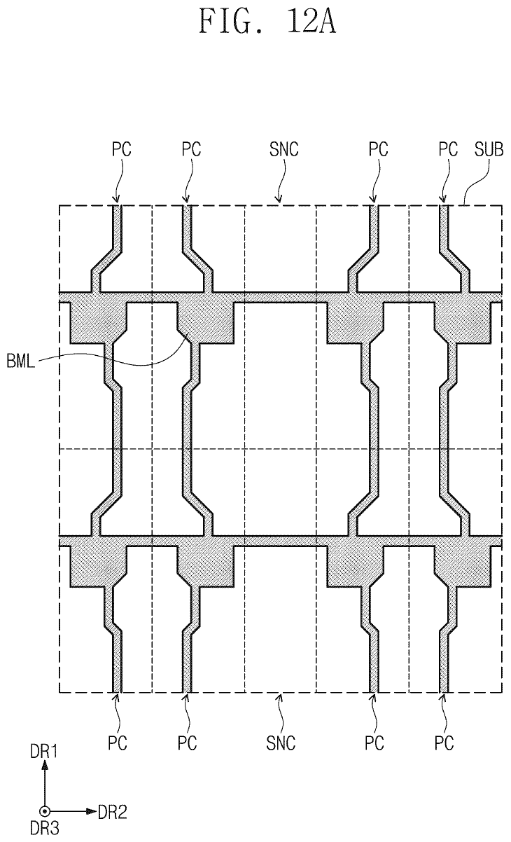

FIG. 10 is a plan view illustrating a connection of data lines DL, vertical lines VBRS, and horizontal lines HBRS. FIG. 11 is a plan view illustrating a connection of readout lines RX, the vertical lines VBRS, and the horizontal lines HBRS.

Referring to FIGS. 10 and 11, the display panel DP may have different widths in the second direction DR2 depending on areas. A first portion PT1 where the data driver 200 is disposed may have a relatively small width in the second direction DR2, and a second portion PT2 where the pixels PX are disposed may have a relatively large width in the second direction DR2. In this case, it may be difficult for the data lines DL to directly extend from the data driver 200 to a partial area of the first portion PT1 (e.g., the left area in FIG. 10). The density of signal lines may increase in a concave area that forms the boundary between the first portion PT1 and the second portion PT2, and short circuit defects between the signal lines may occur in the corresponding area. To suppress the short circuit defects, the present disclosure may apply a bypass wiring structure. Hereinafter, the bypass wiring structure will be described.

In FIGS. 10 and 11, only some data lines DL, some readout lines RX, some vertical lines VBRS, and some horizontal lines HBRS are illustrated, and the remaining signal lines are not illustrated. The vertical lines VBRS may include first vertical lines VBRS1, second vertical lines VBRS2, and dummy vertical lines DVBRS. The horizontal lines HBRS may include first horizontal lines HBRS1, second horizontal lines HBRS2, and dummy horizontal lines DHBRS.

Referring to FIG. 10, the first vertical lines VBRS1 and the dummy vertical lines DVBRS may extend in the first direction DR1 and may be arranged in the second direction DR2. The first horizontal lines HBRS1 and the dummy horizontal lines DHBRS may extend in the second direction DR2 and may be arranged in the first direction DR1. When viewed from above the plane, the first vertical lines VBRS1, the dummy vertical lines DVBRS, and the data lines DL may cross the first horizontal lines HBRS1 and the dummy horizontal lines DHBRS.

Some data lines DL adjacent to the left edge of the second portion PT2 may be connected to the data driver 200 through the first vertical lines VBRS1 among the vertical lines VBRS and the first horizontal lines HBRS1 among the horizontal lines HBRS. The following description will be focused on one data line DL illustrated by a thick line in FIG. 10. The first vertical line VBRS1 may be connected to the data driver 200, and the first horizontal line HBRS1 may be connected to the first vertical line VBRS1. In addition, the first horizontal line HBRS1 may be connected to the data line DL adjacent to the left edge of the second portion PT2.

The dummy vertical lines DVBRS and the dummy horizontal lines DHBRS correspond to vertical lines VBRS and horizontal lines HBRS that are not electrically connected to data lines and the data driver 200. The dummy vertical lines DVBRS may not be connected to the data driver 200. The dummy horizontal lines DHBRS may not be connected to the data lines DL and the dummy vertical lines DVBRS.

Referring to FIG. 11, the second vertical lines VBRS2 and the dummy vertical lines DVBRS may extend in the first direction DR1 and may be arranged in the second direction DR2. The second horizontal lines HBRS2 and the dummy horizontal lines DHBRS may extend in the second direction DR2 and may be arranged in the first direction DR1. The readout lines RX may extend in the first direction DR1 and may be arranged in the second direction DR2. When viewed from above the plane, the second vertical lines VBRS2, the dummy vertical lines DVBRS, and the readout lines RX may cross the second horizontal lines HBRS2 and the dummy horizontal lines DHBRS.

The readout lines RX may be electrically connected to the readout circuit 500, and the readout circuit 500 may read the sensing signal RS described with reference to FIG. 5. For a reason similar to that described in relation to the data lines DL, it may be difficult for some readout lines RX disposed adjacent to the left edge of the second portion PT2 to be directly connected to the readout circuit 500.

The readout lines RX disposed adjacent to the left edge of the second portion PT2 may be connected to the readout circuit 500 through some of the vertical lines VBRS and some of the horizontal lines HBRS. The following description will be focused on one readout line RX illustrated by a thick line in FIG. 11. The second vertical line VBRS2 may be connected to the readout circuit 500, and the second horizontal line HBRS2 may be connected to the second vertical line VBRS2. The second horizontal line HBRS2 may be connected to the readout line RX. The dummy vertical lines DVBRS and the dummy horizontal lines DHBRS correspond to vertical lines VBRS and horizontal lines HBRS that are not electrically connected to the readout circuit 500 and the readout line RX.

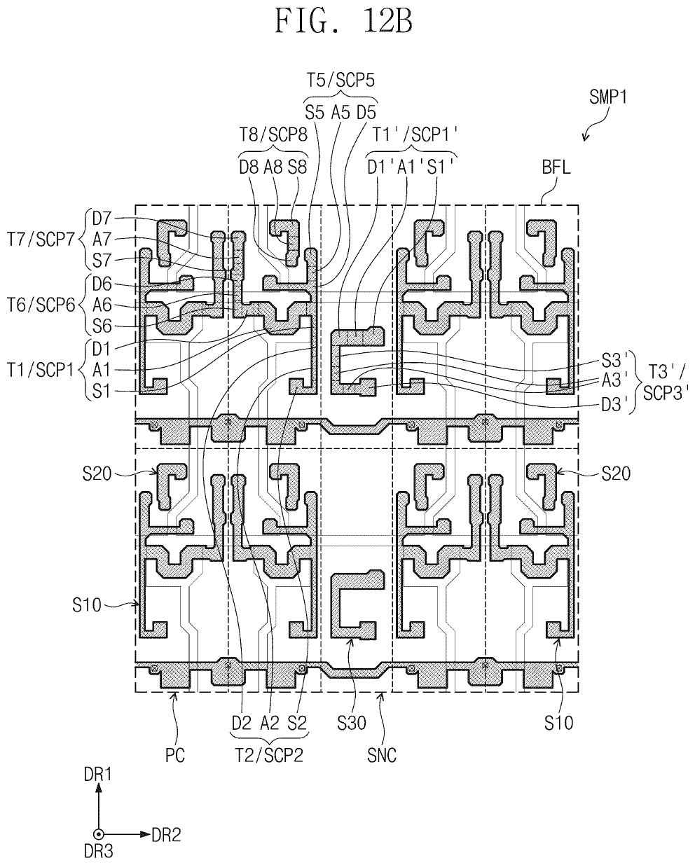

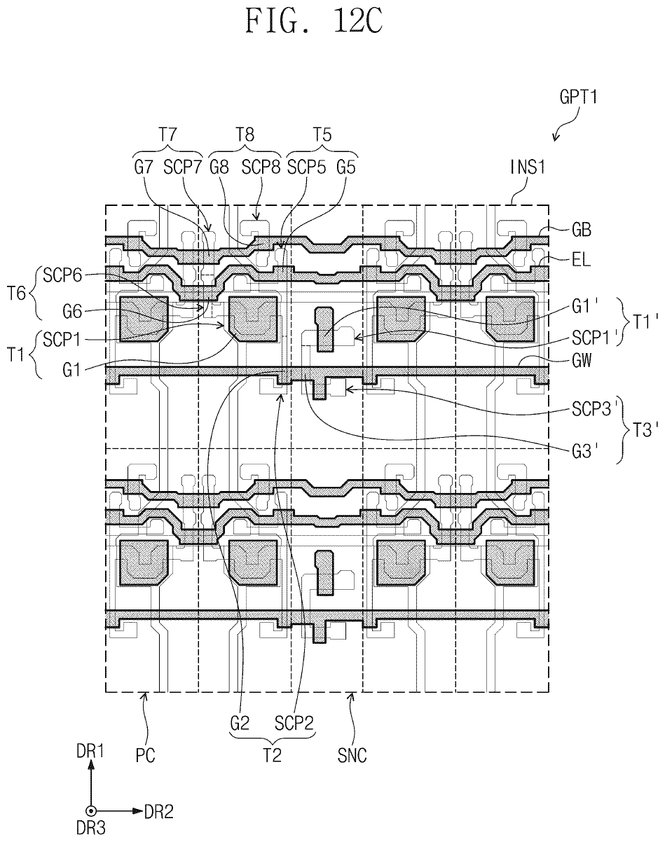

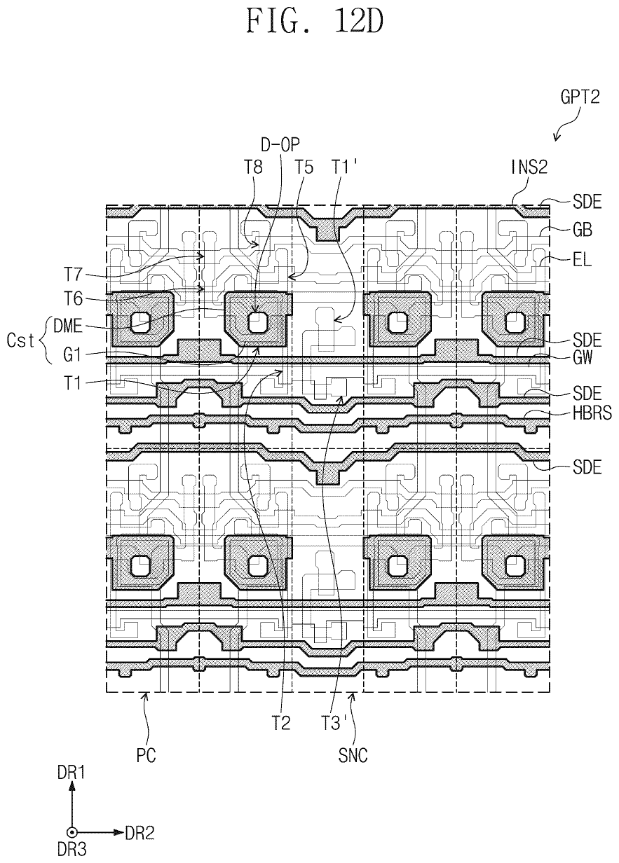

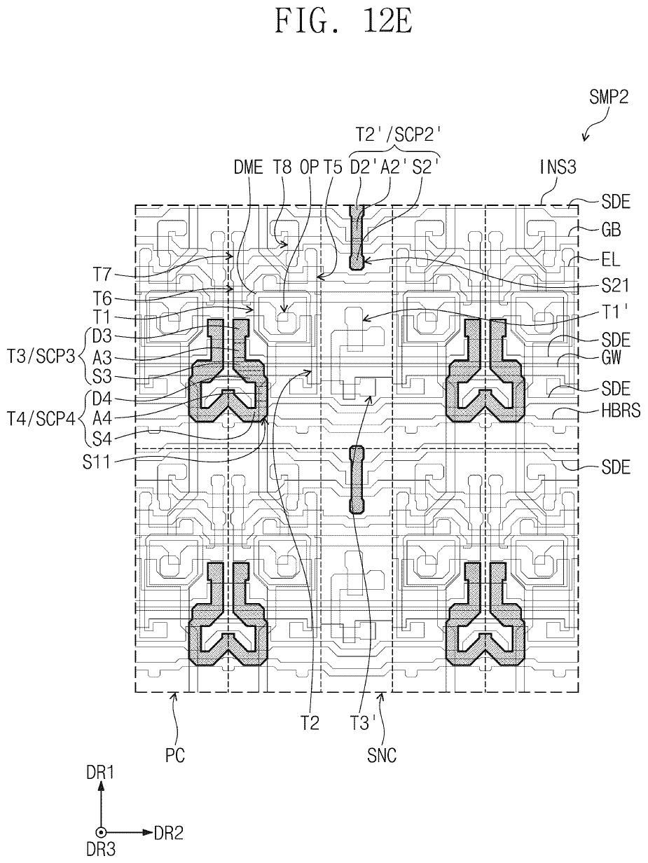

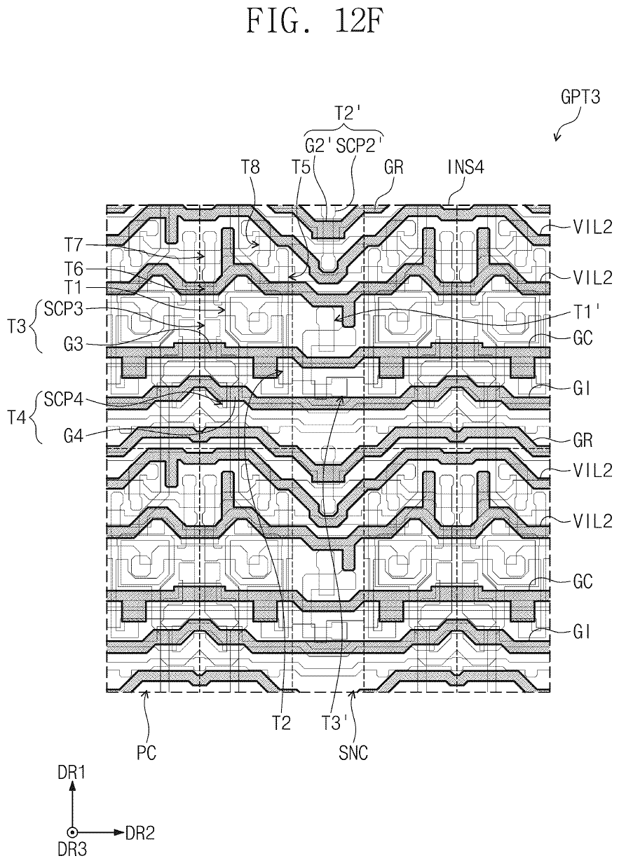

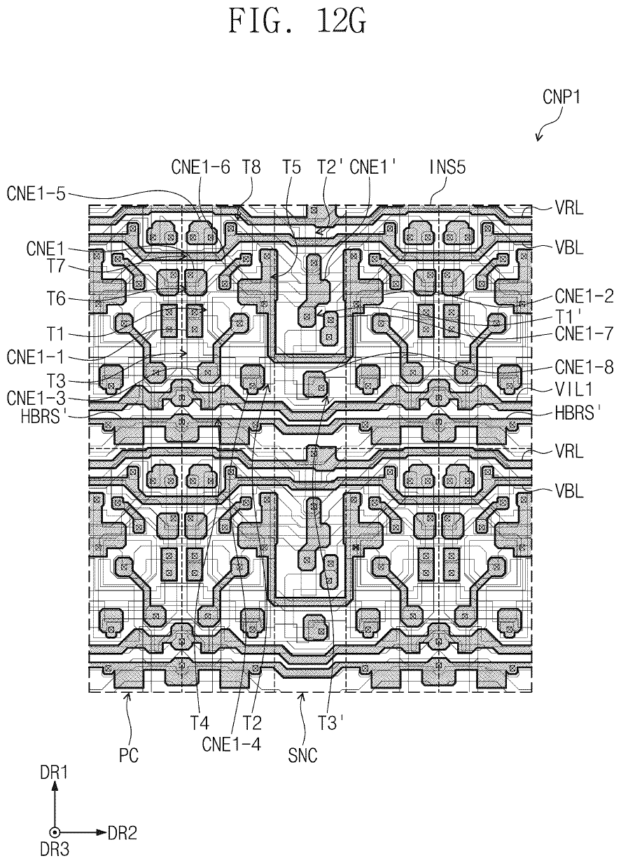

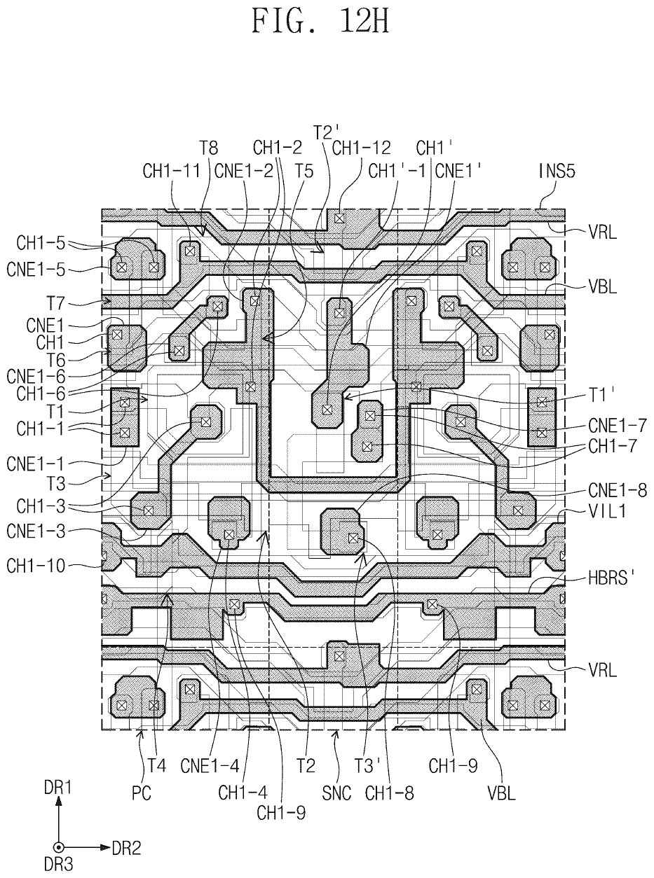

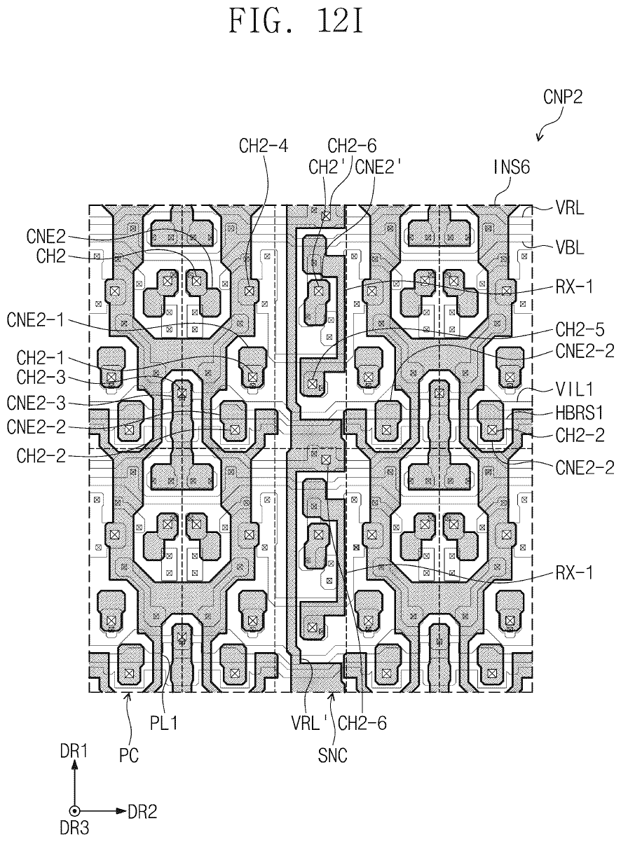

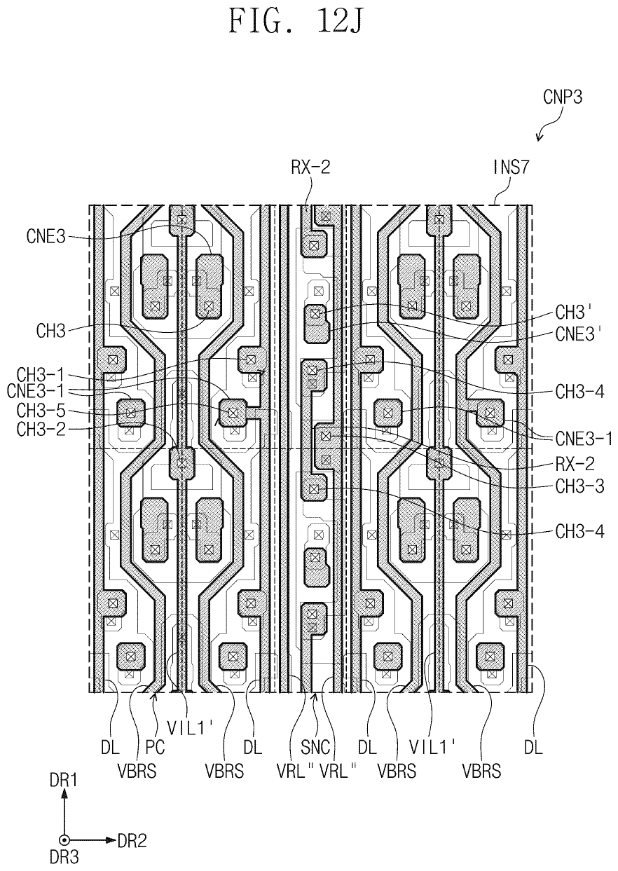

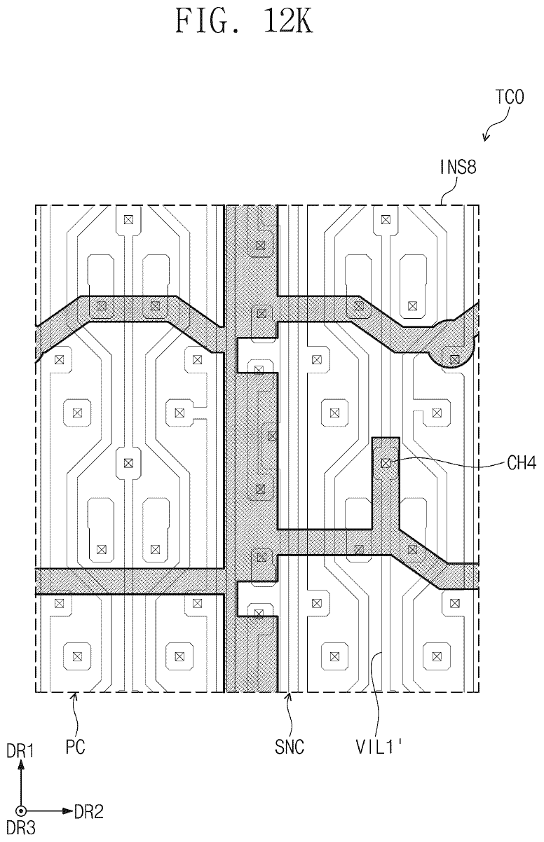

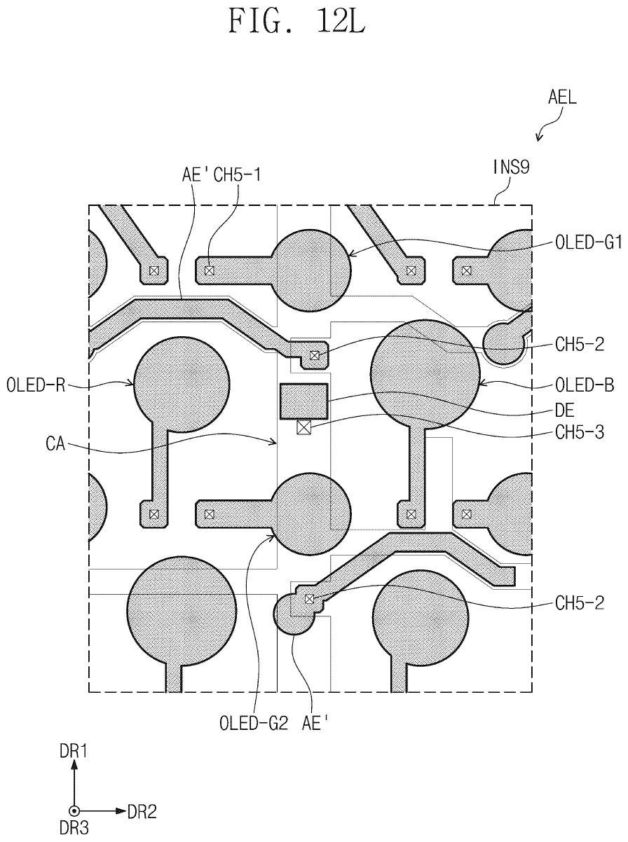

FIGS. 12A to 12M are plan views illustrating a stacked structure of the pixels PX and the light sensors SN.

FIGS. 12A to 12M illustrate an area corresponding to eight pixel driving circuits PC and two sensor driving circuits SNC disposed adjacent to one another in the first direction DR1 illustrated in FIG. 8. Each of the pixel driving circuits PC described with reference to FIGS. 12A to 12M may correspond to the equivalent circuit of the pixel driving circuit PC illustrated in FIG. 5, and each of the sensor driving circuits SNC described with reference to FIGS. 12A to 12M may correspond to the equivalent circuit of the sensor driving circuit SNC illustrated in FIG. 5.

In FIGS. 12A to 12M, the boundaries between the pixel driving circuits PC and the sensor driving circuits SNC are illustrated by dotted lines. In FIG. 12A, the reference numerals of the pixel driving circuits PC and the sensor driving circuits SNC are all illustrated. However, in FIGS. 12B to 12M, only the reference numerals of one pixel driving circuit PC and one sensor driving circuit SNC are illustrated. The following description of FIGS. 12A to 12M will be focused on the configuration of one pixel driving circuit PC among the plurality of pixel driving circuits PC and the configuration of one sensor driving circuit SNC among the sensor driving circuits SNC.

FIG. 12A illustrates the component disposed on the base layer SUB illustrated in FIGS. 6 and 7. In FIGS. 12A to 12K, the buffer layer BFL and the first to ninth insulating layers INS1 to INS9 are additionally stacked as in FIGS. 6 and 7. For example, the components additionally illustrated in FIG. 12B are disposed on the buffer layer BFL. FIG. 12B to 12L illustrate patterns of conductive layers or patterns of semiconductor layers and the first to ninth insulating layers INS1 to INS9 formed through a photolithography process on the buffer layer BFL. In FIGS. 12A to 12M, the reference numerals of unnecessary components in the description of the features of the corresponding drawings are not illustrated.

Referring to FIG. 12A, the shielding layer BML may be disposed on the base layer SUB. A conductive layer entirely overlapping the base layer SUB may be subjected to patterning through a photolithography process to form the shielding layer BML. The shielding layer BML may have various shapes without being limited to the shape illustrated in FIG. 12A. Hereinafter, conductive patterns or semiconductor patterns disposed on one insulating layer are formed through a photolithography process unless otherwise described. The shielding layer BML overlaps the semiconductor layer SCP1 of the first transistor T1 that will be described below.

Referring to FIG. 12B, a first semiconductor pattern SMP1 may be disposed on the buffer layer BFL. The first semiconductor pattern SMP1 refers to the pattern of the first semiconductor layer. The first semiconductor pattern SMP1 may have various shapes without being limited to the shape illustrated in FIG. 12B.

The first semiconductor pattern SMP1 includes a first pattern S10 and a second pattern S20 disposed in each of the pixel driving circuits PC. In addition, the first semiconductor pattern SMP1 includes a third pattern S30 disposed in each of the sensor driving circuits SNC. The first pattern S10, the second pattern S20, and the third pattern S30 may be spaced apart from one another. Portions of the first pattern S10, the second pattern S20, and the third pattern S30 may form the first, second, fifth, sixth, seventh, and eighth source areas S1, S2, S5, S6, S7, and S8, the first, second, fifth, sixth, seventh, and eighth drain areas D1, D2, D5, D6, D7, and D8, and the first, second, fifth, sixth, seventh, and eighth channel areas A1, A2, A5, A6, A7, and A8 of the first, second, fifth, sixth, seventh, and eighth transistors T1, T2, T5, T6, T7, and T8 and the first and third sensing source areas S1′ and S3′, the first and third sensing drain areas D1′ and D3′, and the first and third sensing channel areas A1′ and A3′ of the first and third sensing transistors T1′ and T3′. Since the state illustrated in FIG. 12B corresponds to a state prior to doping, the channel areas A1, A2, A5, A6, A7, A8, A1′, and A3′ are not substantially distinguished from the source areas S1, S2, S5, S6, S7, S8, S1′, and s3′ and the drain areas D1, D2, D5, D6, D7, D8, D1′, and D3′.

The first pattern S10 may include the semiconductor layer SCP1 (hereinafter, referred to as the first semiconductor layer) of the first transistor T1, the semiconductor layer SCP2 (hereinafter, referred to as the second semiconductor layer) of the second transistor T2, the semiconductor layer SCP5 (hereinafter, referred to as the fifth semiconductor layer) of the fifth transistor T5, the semiconductor layer SCP6 (hereinafter, referred to as the sixth semiconductor layer) of the sixth transistor T6, and the semiconductor layer SCP7 (hereinafter, referred to as the seventh semiconductor layer) of the seventh transistor T7. The second pattern S20 may include the semiconductor layer SCP8 (hereinafter, referred to as the eighth semiconductor layer) of the eighth transistor T8, and the third pattern S30 may include the semiconductor layer SCP1′ (hereinafter, referred to as the first sensing semiconductor layer) of the first sensing transistor T1′ and the semiconductor layer SCP3′ (hereinafter, referred to as the third sensing semiconductor layer) of the third sensing transistor T3′. Each of the channel areas A1, A2, A5, A6, A7, A8, A1′, and A3′ is disposed between a corresponding source area among the source areas S1, S2, S5, S6, S7, S8, S1′, and S3′ and a corresponding drain area among the drain areas D1, D2, D5, D6, D7, D8, D1′, and D3′. The second, fifth, sixth, seventh, and eighth semiconductor layers SCP2, SCP5, SCP6, SCP7, and SCP8 and the first and third sensing semiconductor layers SCP1′ and SCP3′ may have the same structure as the first semiconductor layer SCP1 described with reference to FIG. 6.

The second drain area D2 of the second transistor T2 and the fifth drain area D5 of the fifth transistor T5 may extend from the first source area S1 of the first transistor T1. The sixth source area S6 of the sixth transistor T6 may extend from the first drain area D1 of the first transistor T1. The seventh source area S7 of the seventh transistor T7 may extend from the sixth drain area D6 of the sixth transistor T6.

Depending on this structure, the first transistor T1 may be electrically connected to the second, fifth, and sixth transistors T2, T5, and T6, and the seventh transistor T7 may be electrically connected to the sixth transistor T6. The eighth semiconductor layer SPC8 may be disposed adjacent to the fifth semiconductor layer SPC5.

The third source area S3′ of the third sensing transistor T3′ may extend from the first drain area D1′ of the first sensing transistor T1′. Accordingly, the first sensing transistor T1′ may be electrically connected to the third sensing transistor T3′. The third pattern S30 may be disposed adjacent to the second semiconductor layer SCP2. The third sensing transistor T3′ may include two transistors connected in series. Accordingly, the third sensing transistor T3′ may include two third channel areas A3′. An area between the two third channel areas A3′ serves as a drain area as well as a source area.

In the following drawings, the ordinal numbers i-th and j-th indicating the order of the above-described lines are omitted. Scan lines corresponding to two pixel rows are illustrated, and the following description will be focused on scan lines corresponding to one pixel row.

Referring to FIG. 12C, a first conductive pattern group GPT1 is disposed on the first insulating layer INS1. The first conductive pattern group GPT1 includes a plurality of conductive patterns. The plurality of conductive patterns are formed by making a conductive layer subject to patterning through a photolithography process. A plurality of conductive pattern groups that will be described below may also be formed in the same manner. In FIG. 12C and the following drawings, the first, second, fifth, sixth, seventh, and eighth semiconductor layers SCP1, SCP2, SCP5, SCP6, SCP7, and SCP8 and the first and third sensing semiconductor layers SCP1′ and SCP3′ are briefly illustrated without distinction between the channel areas A1, A2, A5, A6, A7, A8, A1′, and A3′, the source areas S1, S2, S5, S6, S7, S8, S1′, and S3′, and the drain areas D1, D2, D5, D6, D7, D8, D1′, and D3′.

The first conductive pattern group GPT1 may include a write scan line GW, a light emission line EL, a bias scan line GB, the first gate electrode G1, and the first sensing gate electrode G1′. The write scan line GW, the light emission line EL, and the bias scan line GB may extend in the second direction DR2. The light emission line EL may be disposed between the write scan line GW and the bias scan line GB. The first gate electrode G1 and the first sensing gate electrode G1′ may be disposed between the write scan line GW and the light emission line EL.

One portion of the write scan line GW that overlaps the second semiconductor layer SCP2 corresponds to the second gate electrode G2, and another portion of the write scan line GW that overlaps the third sensing semiconductor layer SCP3′ corresponds to the third sensing gate electrode G3′. The third sensing transistor T3′ may further include another third sensing gate electrode G3′ protruding downward from the write scan line GW in a plan view. The second gate electrode G2 overlaps the channel area A2 (refer to FIG. 12B) of the second semiconductor layer SCP2, and the two third sensing gate electrodes G3′ overlap the two channel areas A3′ (refer to FIG. 12B) of the third sensing semiconductor layer SCP3′, respectively. Hereinafter, even though there is no separate description, the expression “a gate electrode overlaps a semiconductor layer” means that the gate electrode overlaps the channel area of the semiconductor layer.

One portion of the light emission line EL that overlaps the fifth semiconductor layer SCP5 corresponds to the fifth gate electrode G5, and another portion of the light emission line EL that overlaps the sixth semiconductor layer SCP6 corresponds to the sixth gate electrode G6. One portion of the bias scan line GB that overlaps the seventh semiconductor layer SCP7 corresponds to the seventh gate electrode G7, and another portion of the bias scan line GB that overlaps the eighth semiconductor layer SCP8 corresponds to the eighth gate electrode G8. The first gate electrode G1 overlaps the first semiconductor layer SCP1, and the first sensing gate electrode G1′ overlaps the first sensing semiconductor layer SCP1′.

A doping process may be performed after the first conductive pattern group GPT1 is formed on the first insulating layer INS1. The first, second, fifth, sixth, seventh, and eighth gate electrodes G1, G2, G5, G6, G7, and G8 and the first and third sensing gate electrodes G1′ and G3′ described above serve as a self-aligned mask in the doping process.

Referring to FIG. 12D, a second conductive pattern group GPT2 is disposed on the second insulating layer INS2. In FIG. 12D and the following drawings, the first, second, fifth, sixth, seventh, and eighth transistors T1, T2, T5, T6, T7, and T8 and the first and third sensing transistors T1′ and T3′ are briefly illustrated without distinction of the semiconductor layers SCP1, SCP2, SCP5, SCP6, SCP7, SCP8, SCP1′, and SCP3′ and the gate electrodes G1, G2, G5, G6, G7, G8, G1′, and G3′.

The second conductive pattern group GTP2 may include the additional electrode DME, a plurality of sub-lines SDE, and the horizontal line HBRS. The additional electrode DME may overlap the above-described first gate electrode G1. The additional electrode DME may form the capacitor CST together with the first gate electrode G1. An opening D-OP may be defined in the additional electrode DME. Hereinafter, the opening D-OP of the additional electrode DME is defined as an electrode opening D-OP to distinguish from other openings.

Three sub-lines SDE illustrated as an example may extend in the second direction DR2 and may be arranged in the first direction DR1. When viewed from above the plane, the three sub-lines SDE may overlap a reset scan line GR, a compensation scan line GC, and an initialization scan line GI illustrated in FIG. 12F.

The horizontal line HBRS may extend in the second direction DR2. In this embodiment, the horizontal line HBRS may correspond to one first horizontal line HBRS1 connected to the data line DL illustrated in FIG. 10, but is not limited thereto. The horizontal line HBRS may be the second horizontal line HBRS2 of FIG. 11. The horizontal line HBRS may be disposed between pixel driving circuits PC disposed adjacent to each other in the first direction DR1 and may be disposed between sensor driving circuits SNC disposed adjacent to each other in the first direction DR1.

Referring to FIG. 12E, a second semiconductor pattern SMP2 may be disposed on the third insulating layer INS3. The second semiconductor pattern SMP2 includes a first pattern S11 disposed in each of the pixel driving circuits PC and a second pattern S21 disposed in each of the sensor driving circuits SNC. The first pattern S11 and the second pattern S21 may be spaced apart from each other. The first pattern S11 may include the semiconductor layer SCP3 (hereinafter, referred to as the third semiconductor layer) of the third transistor T3 and the semiconductor layer SCP4 (hereinafter, referred to as the fourth semiconductor layer) of the fourth transistor T4.

The first pattern S11 and the second pattern S21 may correspond to the source areas S3, S4, and S2′, the drain areas D3, D4, and D2′, and the channel areas A3, A4, and A2′ of the transistors T3, T4, and T2′. The fourth drain area D4 of the fourth transistor T4 may extend from the third source area S3 of the third transistor T3. Depending on this structure, the fourth transistor T4 may be electrically connected to the third transistor T3.

Referring to FIG. 12F, a third conductive pattern group GPT3 is disposed on the fourth insulating layer INS4. In FIG. 12 and the following drawings, the reference numerals of the sub-lines SDE that overlap the reset scan line GR, the compensation scan line GC, and the initialization scan line GI are omitted.

The third conductive pattern group GPT3 may include the reset scan line GR, the compensation scan line GC, the initialization scan line GI, and the second initialization line VIL2. In this embodiment, two second initialization lines VIL2 may be disposed to correspond to one pixel driving circuit PC and one sensor driving circuit SNC of FIG. 12A. In FIG. 12F, only a portion of the reset scan line GR that corresponds to the pixel driving circuits PC and the sensor driving circuit SNC disposed on the upper side is illustrated. The reset scan line GR illustrated in the middle of FIG. 12F corresponds to the pixel driving circuits PC and the sensor driving circuit SNC disposed on the lower side.

The reset scan line GR, the compensation scan line GC, the initialization scan line GI, and the second initialization lines VIL2 may extend in the second direction DR2 and may be arranged in the first direction DR1. The compensation scan line GC may be disposed between the initialization scan line GI and the second initialization lines VIL2. The second initialization lines VIL2 may be disposed between the reset scan line GR and the compensation scan line GC. The second initialization lines VIL2 may be disposed adjacent to the seventh and eighth transistors T7 and T8 and the first and second sensing transistors T1′ and T2′.

A portion of the compensation scan line GC that overlaps the second semiconductor layer SCP3 in FIG. 12F corresponds to the third gate electrode G3. A portion of the initialization scan line GI that overlaps the fourth semiconductor layer SCP4 in FIG. 12F corresponds to the fourth gate electrode G4. A portion of the reset scan line GR that overlaps the second sensing semiconductor layer SCP2′ in FIG. 12F corresponds to the second sensing gate electrode G2′.

Hereinafter, in FIGS. 12G to 12M, for simplification of reference numerals, the reference numerals of the third and fourth source areas S3 and S4, the third and fourth drain areas D3 and D4, the third and fourth channel areas A3 and A4, and the third and fourth gate electrodes G3 and G4 will be omitted. Furthermore, the reference numerals of the second source area S2′, the second drain area D2′, the second channel area A2′, and the second gate electrode G2′ will also be omitted. In addition, in FIGS. 12G to 12M, the reference numerals of the write scan line GW, the compensation scan line GC, the initialization scan line GI, the bias scan line GB, and the reset scan line GR will also be omitted. In FIGS. 12G to 12M, the reference numerals of the first to eighth transistors T1 to T8 and the first to third sensing transistors T1′ to T3′ are illustrated.

Referring to FIGS. 12G and 12H, a fourth conductive pattern group CNP1 is disposed on the fifth insulating layer INS5. The fourth conductive pattern group CNP1 may include a plurality of conductive patterns. FIG. 12H illustrates an enlarged view of a partial area of FIG. 12G in order to increase the identifiability of the drawing.

The fourth conductive pattern group CNP1 may include first connecting electrodes CNE1, CNE1′, and CNE1-1 to CNE1-8, a horizontal line HBRS′, the first initialization line VIL1, the reset line VRL, and the bias line VBL. The first connecting electrode CNE1 of FIGS. 12G and 12H may be the first connecting electrode CNE1 illustrated in FIG. 6, and the first connecting electrode CNE1′ may be the first connecting electrode CNE1′ illustrated in FIG. 7. Electrodes connected with conductive patterns or semiconductor patterns on the lower side other than the above-described signals lines among the conductive patterns of the fourth conductive pattern group CNP1 are defined as the first connecting electrodes CNE1, CNE1′, and CNE1-1 to CNE1-8. The first connecting electrodes CNE1, CNE1′, and CNE1-1 to CNE1-8 are connected to different patterns among the conductive patterns or the semiconductor patterns on the lower side. All of the first connecting electrodes CNE1, CNE1′, and CNE1-1 to CNE1-8 have the same name “first connecting electrode”, but may be distinguished from one another by the reference numerals in the drawings.

The first initialization line VIL1, the reset line VRL, and the bias line VBL may extend in the second direction DR2. The first initialization line VIL1 may be disposed adjacent to the fourth transistor T4. The reset line VRL may be adjacent to the second sensing transistor T2′. The bias line VBL may be adjacent to the eighth transistor T8.

A plurality of first contact holes CH1, CH1′, CH1-1 to CH1-12, and CH1′-1 penetrating at least the fifth insulating layer INS5 may be defined in the fifth insulating layer INS5. The plurality of first contact holes CH1, CH1′, CH1-1 to CH1-12, and CH1′-1 are formed through the same photolithography process and expose different portions of conductive patterns or semiconductor patterns disposed under the fifth insulating layer INS5.

The first contact hole CH1 overlapping the sixth transistor T6 is the first contact hole CH1 illustrated in FIG. 6. The first contact hole CH1′ overlapping the first sensing transistor T′ is the first contact hole CH1′ illustrated in FIG. 7. Some of the first contact holes CH1-1 to CH1-12 and CH1′-1 may penetrate the first to fifth insulating layers INS1 to INS like the first contact hole CH1 illustrated in FIG. 6, and other first contact holes may penetrate the second to fifth insulating layers INS2 to INS5 like the first contact hole CH1′ illustrated in FIG. 7. The other first contact holes may penetrate two or three insulating layers among the first to fifth insulating layers INS1 to INS5.

The first connecting electrode CNE1 may be connected to the sixth drain area D6 (refer to FIG. 12B) through the first contact hole CH1. The first connecting electrode CNE1′ may be connected to the first sensing gate electrode G1′ (refer to FIG. 12C) through the first contact hole CH1′. The first connecting electrode CNE1′ may be connected to the second source area S2′ (refer to FIG. 12E) through the first contact hole CH1′-1. That is, the first connecting electrode CNE1′ connects the first sensing gate electrode G1′ and the second source area S2′.

The first connecting electrode CNE1-1 may connect the first and sixth transistors T1 and T6 to the third transistor T3 through the first contact holes CH1-1. Like the first connecting electrode CNE1-1 and the first contact holes CH1-1, a connecting electrode and contact holes associated with the connecting electrode have similar reference numerals. However, two first contact holes CH1-1 are not limited to the same contact holes. The two first contact holes CH1-1 may penetrate different numbers of insulating layers.

The first connecting electrode CNE1-2 connects the fifth transistor T5 and the capacitor CST through the first contact holes CH1-2. The first connecting electrode CNE1-2 may be connected to the additional electrode DME (refer to FIG. 12D) and the fifth source area S5 (refer to FIG. 12B). The first connecting electrode CNE1-3 connects the third and fourth transistors T3 and T4 to the first transistor T1 through the first contact holes CH1-3. The first connecting electrode CNE1-3 may connect the third source area S3 (refer to FIG. 12E) and the fourth drain area D4 (refer to FIG. 12E) to the first gate electrode G1 (refer to FIG. 12C). The first connecting electrode CNE1-3 may pass through the electrode opening D-OP (refer to FIG. 12D) and may be connected to the first gate electrode G1.

The first connecting electrode CNE1-4 may be connected to the second transistor T2 through the first contact hole CH1-4. The first connecting electrode CNE1-4 may be connected to the second source area S2 (refer to FIG. 12B). The first connecting electrode CNE1-5 may connect the seventh transistor T7 to the second initialization line VIL2 through the first contact holes CH1-5. The first connecting electrode CNE1-5 may be connected to the seventh drain area D7 (refer to FIG. 12B) and a partial area of the second initialization line VIL2 (refer to FIG. 12F).

The first connecting electrode CNE1-6 may connect the fifth transistor T5 and the eighth transistor T8 through the first contact holes CH1-6. The first connecting electrode CNE1-6 may be connected to the fifth drain area D5 (refer to FIG. 12B) and the eighth drain area D8 (refer to FIG. 12B). The first connecting electrode CNE1-7 may connect the first sensing transistor T1′ to the second initialization line VIL2 through the first contact holes CH1-7. The first connecting electrode CNE1-7 may be connected to the first source area S1′ (refer to FIG. 12B) and a partial area of the second initialization line VIL2 (refer to FIG. 12F).

The first connecting electrode CNE1-8 may be connected to the third sensing transistor T3′ through the first contact hole CH1-8. The first connecting electrode CNE1-8 may be connected to the third drain area D3′ (refer to FIG. 12B). The horizontal line HBRS′ may be connected to the horizontal line HBRS (refer to FIG. 12E) through the first contact hole CH1-9. The first connecting electrode CNE1-8 may be connected to the third drain area D3′ (refer to FIG. 12B). The first initialization line VIL1 may be connected to the fourth transistor T4 through the first contact hole CH1-10. The first initialization line VIL1 may be connected to the fourth source area S4 (refer to FIG. 12E).

The bias line VBL may be connected to the eighth transistor T8 through the first contact hole CH1-11. The bias line VBL may be connected to the eighth source area S8 (refer to FIG. 12B). The reset line VRL may be connected to the second sensing transistor T2′ through the first contact hole CH1-12. The reset line VRL may be connected to the second drain area D2′ (refer to FIG. 12E).

Hereinafter, in FIGS. 12I to 12M, conductive patterns and semiconductor patterns disposed under the fourth conductive pattern group CNP1 are not illustrated to increase the identifiability of the drawings. In addition, each of FIGS. 121 to 12M illustrates only the components added to the previous drawings and the components added to the corresponding drawing. The components added to the previous drawings are illustrated by thin lines, and the components added to the corresponding drawing are illustrated by thick lines. Hatching is additionally drawn on the components added to the corresponding drawing.

Referring to FIG. 12I, a fifth conductive pattern group CNP2 is disposed on the sixth insulating layer INS6. The fifth conductive pattern group CNP2 may include second connecting electrodes CNE2, CNE2′, and CNE2-1 to CNE2-3, the first power line PL1, first portions RX-1 of a readout line, and a reset line VRL′.

The first power line PL1 may extend in the first direction DR1 and may overlap the pixel driving circuit PC. The reset line VRL′ may extend in the first direction DR1 and may overlap the sensor driving circuit SNC. The first portions RX-1 of the readout line are spaced apart from each other in the first direction DR1. The first portions RX-1 are connected with second portions RX-2 of FIG. 12J that will be described below and define a readout line RX of FIG. 12J.

The second connecting electrode CNE2 of FIG. 12I may be the second connecting electrode CNE2 illustrated in FIG. 6, and the second connecting electrode CNE2′ of FIG. 12I may be the second connecting electrode CNE2′ illustrated in FIG. 7. A plurality of second contact holes CH2-1 to CH2-6 are defined in the sixth insulating layer INS6. The plurality of second contact holes CH2-1 to CH2-6 may penetrate at least the sixth insulating layer INS6 and may additionally penetrate the insulating layers disposed under the sixth insulating layer INS6.

The second contact hole CH2 is the second contact hole CH2 illustrated in FIG. 6, and the second contact hole CH2′ is the second contact hole CH2′ illustrated in FIG. 7. The second connecting electrode CNE2 may be connected to the first connecting electrode CNE1 (refer to FIGS. 12G and 12H) through the second contact hole CH2. Accordingly, the second connecting electrode CNE2 may be connected to the sixth transistor T6 through the first connecting electrode CNE1. The second connecting electrode CNE2′ may be connected to the first connecting electrode CNE1′ (refer to FIGS. 12G and 12H) through the second contact hole CH2′. Accordingly, the second connecting electrode CNE2′ may be connected to the second sensing transistor T2′ through the first connecting electrode CNE1′.

The second connecting electrode CNE2-1 may be connected to the first connecting electrode CNE1-4 (refer to FIGS. 12G and 12H) through the second contact hole CH2-1. Accordingly, the second connecting electrode CNE2-1 may be connected to the second transistor T2 through the first connecting electrode CNE1-4.

A plurality of second connecting electrodes CNE2-2 may be provided. The second connecting electrodes CNE2-2 may be arranged in the second direction DR2. The second connecting electrodes CNE2-2 may overlap the horizontal line HBRS′ on the lower side. The second connecting electrodes CNE2-2 are connected to the horizontal line HBRS′ through the second contact hole CH2-2. As a result, the second connecting electrodes CNE2-2 may be connected to the horizontal line HBRS through the horizontal line HBRS′.

The second connecting electrode CNE2-3 may be connected to the first initialization line VIL1 through the second contact hole CH2-3. The second connecting electrode CNE2-3 may be disposed between the pixel driving circuits PC spaced apart from each other in the first direction DR1. In FIG. 12I, two second connecting electrodes CNE2-3 are illustrated in the center of the drawing. In this embodiment, the second connecting electrode CNE2-3 on the left side is connected to the first initialization line VIL1, whereas the second connecting electrode CNE2-3 on the right side is not connected to the first initialization line VIL1 and the horizontal line HBRS′.

Meanwhile, in an embodiment of the present disclosure, the second connecting electrode CNE2-3 on the right side may be connected to the first initialization line VIL1. In this case, the second connecting electrode CNE2-3 on the right side has the same connection relationship as the second connecting electrode CNE2-3 on the left side.

In an embodiment of the present disclosure, the second connecting electrode CNE2-3 on the right side may be connected to the dummy horizontal line DHBRS of FIG. 10. Among three second connecting electrodes CNE2-3 illustrated on the right side in FIG. 12I, a second connecting electrode CNE2-3 disposed on the upper side or a second connecting electrode CNE2-3 disposed on the lower side may be connected to the dummy horizontal line DHBRS. Unlike the first horizontal line HBRS1, the dummy horizontal line DHBRS does not correspond to a component of the bypass wiring structure and serves as a voltage line that receives a constant voltage. For example, the dummy horizontal line DHBRS may receive the second driving voltage ELVSS of FIG. 4.

The first power line PL1 may be connected to the first connecting electrode CNE1-2 (refer to FIGS. 12G and 12H) through the second contact hole CH2-4. Accordingly, the first power line PL1 may be connected to the fifth transistor T5 and the additional electrode DME through the first connecting electrode CNE1-2.

The first portions RX-1 of the readout line may be connected to the first connecting electrode CNE1-8 (refer to FIGS. 12G and 12H) through the second contact hole CH2-5. Accordingly, the readout line RX of FIG. 12J may be connected to the third sensing transistor T3′ through the first connecting electrode CNE1-8.

The reset line VRL′ may be connected to the reset line VRL through the second contact hole CH2-6. The reset line VRL′ may be connected to the second sensing transistor T2′ through the reset line VRL. Unlike the above-described reset line VRL extending in the second direction DR2, the reset line VRL′ extends in the first direction DR1. Accordingly, the reset lines VRL and VRL′ are disposed in a net shape throughout the display area DA (refer to FIG. 4).

Referring to FIG. 12J, a sixth conductive pattern group CNP3 is disposed on the seventh insulating layer INS7. The sixth conductive pattern group CNP3 may include a plurality of conductive patterns. The sixth conductive pattern group CNP3 may include third connecting electrodes CNE3, CNE3′, and CNE3-1, the data line DL, the vertical line VBRS, a first initialization line VIL1′, a reset line VRL″, and the second portions RX-2 of the readout line RX.

The data line DL, the vertical line VBRS, the first initialization line VIL1′, and the reset line VRL″ may extend in the first direction DR1. The data line DL, the first initialization line VIL1′, and the vertical line VBRS may overlap the pixel driving circuit PC, and the reset line VRL″ and the second portions RX-2 of the readout line RX may overlap the sensor driving circuit SNC. A pair of data lines DL and a pair of vertical lines VBRS may be disposed in each of the pixel driving circuits PC, the first initialization line VIL1′ may be disposed in each of the pixel driving circuits PC, and a pair of reset lines VRL″ may be disposed to correspond to the sensor driving circuit SNC. The second portions RX-2 of the readout line RX are spaced apart from each other in the first direction DR1. The second portions RX-2 of the readout line RX are disposed between the pair of reset lines VRL″.

The third connecting electrode CNE3 of FIG. 12J may be the third connecting electrode CEN3 illustrated in FIG. 6. The third connecting electrode CNE3′ may be the third connecting electrode CEN3′ illustrated in FIG. 7. The third connecting electrode CNE3 may be disposed between the first initialization line VIL1′ and the vertical line VBRS. The data line DL may be disposed between the vertical line VBRS and the reset line VRL″.

A plurality of third contact holes CH3, CH3′, and CH3-1 to CH3-5 may be defined in the seventh insulating layer INS7. The plurality of third contact holes CH3, CH3′, and CH3-1 to CH3-5 may penetrate at least the seventh insulating layer INS7 and may additionally penetrate the insulating layers disposed under the seventh insulating layer INS7.

The third contact hole CH3 is the third contact hole CH3 illustrated in FIG. 6, and the third contact hole CH3′ is the third contact hole CH3′ illustrated in FIG. 7. The third connecting electrode CNE3 may be connected to the second connecting electrode CNE2 (refer to FIG. 12I) through the third contact hole CH3. The third connecting electrode CNE3′ may be connected to the second connecting electrode CNE2′ (refer to FIG. 121) through the third contact hole CH3′.

The data line DL may be connected to the second connecting electrode CNE2-1 (refer to FIG. 121) through the third contact hole CH3-1. Accordingly, the data line DL may be connected to the second transistor T2 through the first connecting electrode CNE1-4 and the second connecting electrode CNE2-1.

The first initialization line VIL1′ may be connected to the second connecting electrode CNE2-3 (refer to FIG. 121) through the third contact hole CH3-2. The first initialization line VIL1′ on the left side in FIG. 12J may be connected to the first initialization line VIL1 through the second connecting electrode CNE2-3. The first initialization voltage VINT may be provided to the fourth transistor T4 by the first initialization line VIL1′ and the first initialization line VIL1. Unlike the above-described first initialization line VIL1 extending in the second direction DR2, the first initialization line VIL1′ extends in the first direction DR1. Accordingly, the first initialization lines VIL1 and VIL1′ are disposed in a net shape throughout the display area DA (refer to FIG. 4).

The first initialization line VIL1′ on the right side in FIG. 12J may be connected to the dummy horizontal line DHBRS, which has been described with reference to FIG. 12I, through the second connecting electrode CNE2-3. Although both the first initialization line VIL1′ on the left side and the first initialization line VIL1′ on the right side are referred to as the first initialization line VIL1′, the first initialization line VIL1′ on the right side may substantially correspond to a voltage line that receives the second driving voltage ELVSS.

The reset line VRL″ may be connected to the reset line VRL′ through the third contact hole CH3-3. As a result, the reset line VRL″ may be connected to the reset line VRL through the reset line VRL′. The reset voltage VRST (refer to FIG. 5) may be provided to the second sensing transistor T2′ by the reset line VRL, the reset line VRL′, and the reset line VRL″.

The second portions RX-2 of the readout line RX may be connected to the first portions RX-1 of the readout line RX through the third contact hole CH3-4. Although the readout line RX including the two portions RX-1 and RX-2 disposed on the different layers is illustrated in this embodiment, the present disclosure is not limited thereto. In an embodiment of the present disclosure, the readout line RX may be formed from only the sixth conductive pattern group CNP3.

One of the pair of reset lines VRL″ may be disposed between the readout line RX and one of the data lines DL. The other one of the pair of reset lines VRL″ may be disposed between the readout line RX and another one of the data lines DL. Pulsed data voltages applied to the data lines DL may affect the sensing signal RS (refer to FIG. 5) output through the readout line RX. When viewed from above the plane, the pair of reset lines VRL″ may block an influence of the pulsed data voltages applied to the data lines DL on the readout line RX. That is, the pair of reset lines VRL″ may serve as shielding electrodes.

Each of the third connecting electrodes CNE3-1 may be disposed adjacent to a corresponding data line DL among the data lines DL. The third connecting electrodes CNE3-1 may be disposed to correspond to the pixel driving circuits PC in a one-to-one manner. In other words, the third connecting electrodes CNE3-1 may be disposed to correspond to the second connecting electrodes CNE2-2 in a one-to-one manner. The third connecting electrodes CNE3-1 may be connected to the second connecting electrodes CNE2-2 through the third contact holes CH3-5, respectively. The third connecting electrodes CNE3-1 may be connected to the horizontal line HBRS (refer to FIG. 12D) through the second connecting electrodes CNE2-2 and the horizontal line HBRS′ (refer to FIG. 12H).

As illustrated on the left side with respect to the sensor driving circuit SNC, one data line DL among the data lines DL may be connected to a corresponding third electrode CNE3-1 among the third connecting electrodes CNE3-1. A conductive layer may be subjected to patterning in a photolithography process such that the one data line DL is connected to the corresponding third connecting electrode CNE3-1. As a result, the one data line DL may be connected to the horizontal line HBRS through the corresponding third connecting electrode CNE3-1. This represents the connection relationship between the first horizontal line HBRS1 and the data line DL adjacent to the left edge of the second portion PT2 that have been described with reference to FIG. 10.

As illustrated on the right side with respect to the sensor driving circuit SNC, one vertical line VBRS among the vertical lines VBRS may be connected to a corresponding third electrode CNE3-1 among the third connecting electrodes CNE3-1. A conductive layer may be subjected to patterning in a photolithography process such that the one vertical line VBRS is connected to the corresponding third connecting electrode CNE3-1. For example, the one vertical line VBRS may be integrally formed with the corresponding third connecting electrode CNE3-1. As a result, the one vertical line VBRS may be connected to the horizontal line HBRS through the corresponding third connecting electrode CNE3-1. This represents the connection relationship between the first horizontal line HBRS1 and the first vertical line VBRS1 that have been described with reference to FIG. 10. Meanwhile, for convenience of description, it has been described that the connection point between the horizontal line HBRS and the data line DL is adjacent to the connection point between the horizontal line HBRS and the vertical line VBRS. However, the connection points are spaced far apart from each other such that tens or hundreds of pixel driving circuits PC are disposed between the connection points in the second direction DR2.

Referring to FIG. 12K, a seventh conductive pattern group TCO is disposed on the eighth insulating layer INS8. The seventh conductive pattern group TCO may include transparent conductive oxide. However, without being limited thereto, the seventh conductive pattern group TCO may include the same material as the first to third conductive pattern groups GPT1 to GPT3 described above, or may include the same material as the fourth to sixth conductive pattern groups CNP1 to CNP3. The first to third conductive pattern groups GPT1 to GPT3 may include molybdenum or a molybdenum alloy, and the fourth to sixth conductive pattern groups CNP1 to CNP3 may include aluminum, copper, titanium, or an alloy thereof.

The seventh conductive pattern group TCO may be a shielding electrode overlapping the readout line RX disposed under the seventh conductive pattern group TCO. Hereinafter, the seventh conductive pattern group TCO is referred to as a shielding electrode TCO.

The shielding electrode TCO may prevent electrodes disposed above the readout line RX from affecting the sensing signal RS output through the readout line RX. Accordingly, noise may be prevented from occurring in the sensing signal RS.

The shielding electrode TCO may be connected to the right first initialization line VIL1′ (refer to FIG. 12J) through a fourth contact hole CH4. The fourth contact hole CH4 penetrates the eighth insulating layer INS8. As a result, the shielding electrode TCO may receive the second driving voltage ELVSS. The shielding electrode TCO may be entirely disposed in the display area DA such that a certain pattern is repeated with respect to the pixel driving circuits PC and the sensor driving circuit SNC as illustrated in FIG. 12K. A plurality of fourth contact holes CH4 may be provided. The plurality of fourth contact holes CH4 may regularly arranged in the first direction DR1. The right first initialization line VIL1′ (refer to FIG. 12J) may also be arranged in the display area DA according to a certain rule. As a result, the shielding electrode TCO and the first initialization line VIL1′, which receives the second driving voltage ELVSS, may be regularly connected through the fourth contact holes CH4 in the entire display area DA.

As will be described below, the common electrode of the second electrode (CE, refer to FIG. 6) and the second electrode CE′ (refer to FIG. 7) may be brought into contact with the shielding electrode TCO, and the shielding electrode TCO may serve as an auxiliary electrode or auxiliary wiring that prevents a voltage drop of the common electrode. The shielding electrode TCO that serves as the auxiliary electrode may have a net shape. The shielding electrode TCO may include a first extending portion EX1 extending in the first direction DR1 and second extending portions EX2 extending from the first extending portion EX1 in the second direction DR2. Although not illustrated, the shielding electrode TCO may include a plurality of first extending portions EX1 spaced apart from each other in the second direction DR2. The second extending portions EX2 may be disposed between first extending portions EX1 adjacent to each other among the plurality of first extending portions EX1.

Referring to FIG. 12L, an eighth conductive pattern group AEL is disposed on the ninth insulating layer INS9. The eighth conductive pattern group AEL may include anodes AE of the first light emitting element OLED-R, the second-first light emitting element OLED-G1, the second-second light emitting element OLED-G2, and the third light emitting element OLED-B illustrated in FIG. 8, anodes AE′ of the light sensing elements LRE illustrated in FIG. 8, and a dummy electrode DE disposed in the contact area CA. The anodes AE, the anodes AE′, and the dummy electrode DE may be formed through the same process. The anodes AE, the anodes AE′, and the dummy electrode DE may include the same material and may have the same stacked structure. Referring to FIG. 12L, the anodes AE of the first light emitting element OLED-R, the second-first light emitting element OLED-G1, the second-second light emitting element OLED-G2, and the third light emitting element OLED-B may be disposed around the dummy electrode DE. This may correspond to the reference area RA illustrated in FIG. 8.

Each of the anodes AE of the first light emitting element OLED-R, the second-first light emitting element OLED-G1, the second-second light emitting element OLED-G2, and the third light emitting element OLED-B is connected to a corresponding third connecting electrode CNE3 (refer to FIG. 12J) through a corresponding fifth contact hole among fifth contact holes CH5-1. The fifth contact holes CH5-1 correspond to the fifth contact hole CH5 of FIG. 6.

Each of the anodes AE of the first light emitting element OLED-R, the second-first light emitting element OLED-G1, the second-second light emitting element OLED-G2, and the third light emitting element OLED-B is connected to the corresponding third connecting electrode CNE3 (refer to FIG. 12J) through the corresponding fifth contact hole among the fifth contact holes CH5-1. Each of the anodes AE′ of the light sensing elements LRE is connected to a corresponding third connecting electrode CNE3′ (refer to FIG. 12J) through a corresponding fifth contact hole among fifth contact holes CH5-2. The fifth contact holes CH5-2 correspond to the fifth contact hole CH5′ of FIG. 7.

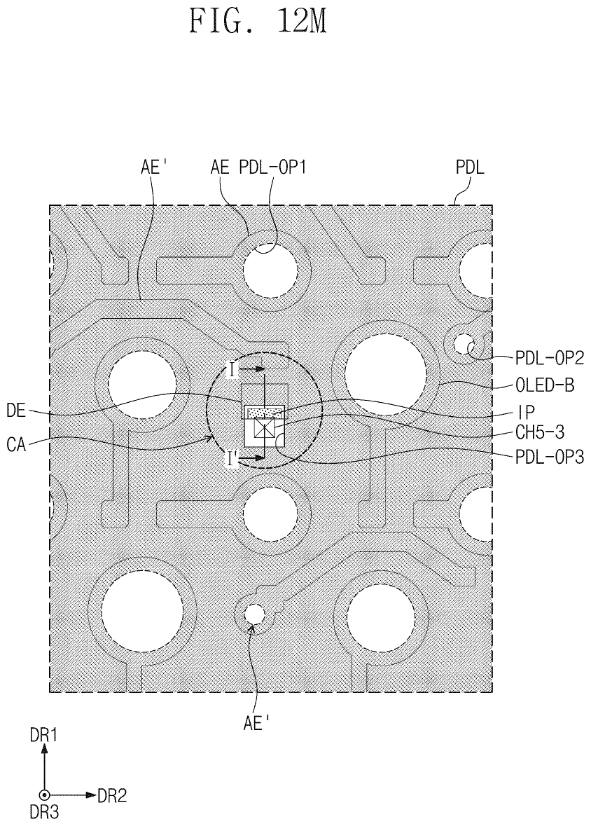

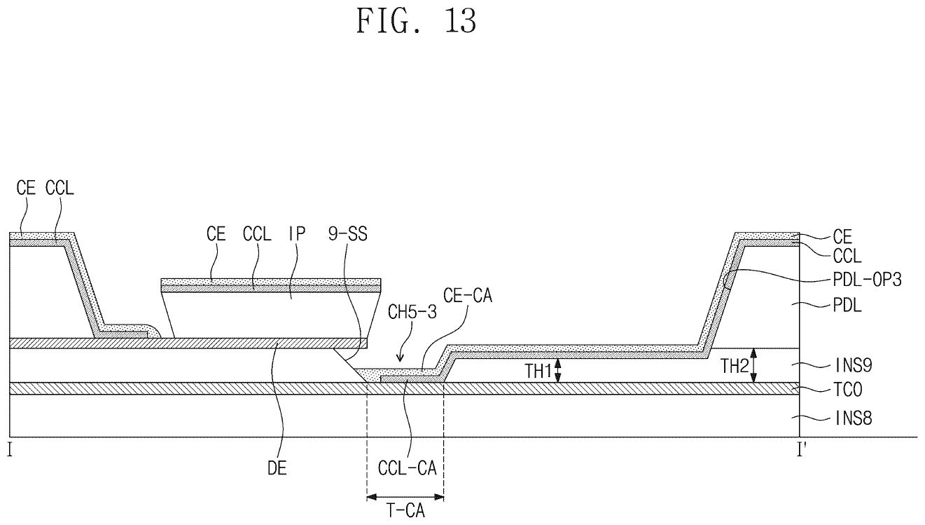

A fifth contact hole CH5-3 is disposed adjacent to the dummy electrode DE when viewed from above the plane. The fifth contact hole CH5-3 exposes the shielding electrode TCO disposed under the fifth contact hole CH5-3. An exposed area of the shielding electrode TCO exposed through the fifth contact hole CH5-3 may be defined as a contact area or a contact portion T-CA (refer to FIG. 13) of the shielding electrode TCO.

Referring to FIG. 12M, the pixel defining layer PDL that covers at least a portion of the eighth conductive pattern group AEL is disposed on the ninth insulating layer INS9. The first openings PDL-OP1 that expose at least portions of the anodes AE of FIG. 12L and the second openings PDL-OP2 that expose at least portions of the anodes AE′ of FIG. 12L are defined in the pixel defining layer PDL.

In addition, a third opening PDL-OP3 that exposes a portion of the dummy electrode DE is defined in the pixel defining layer PDL. The third opening PDL-OP3 is disposed in the contact area CA. The third opening PDL-OP3 has a larger area than the fifth contact hole CH5-3.

An insulating pattern IP spaced apart from the pixel defining layer PDL is disposed in the third opening PDL-OP3. The insulating pattern IP overlaps a portion of the dummy electrode DE. The insulating pattern IP overlaps a portion of the fifth contact hole CH5-3 when viewed from above the plane. In a process of forming the insulating pattern IP, the ninth insulating layer INS9 may also be additionally etched because the area of the third opening PDL-OP3 is wider than the area of the fifth contact hole CH5-3. In other words, the area of the fifth contact hole CH5-3 of FIG. 12M is larger than the area of the fifth contact hole CH5-3 of FIG. 12L. Detailed description thereabout will be given below.

Although not separately illustrated, the hole control layer HCL and the electron control layer ECL may be further disposed on the pixel defining layer PDL and the insulating pattern IP. In addition, the common electrode that is disposed in the first opening PDL-OP1, the second opening PDL-OP2, and the third opening PDL-OP3 may be further disposed on the pixel defining layer PDL and the insulating pattern IP.

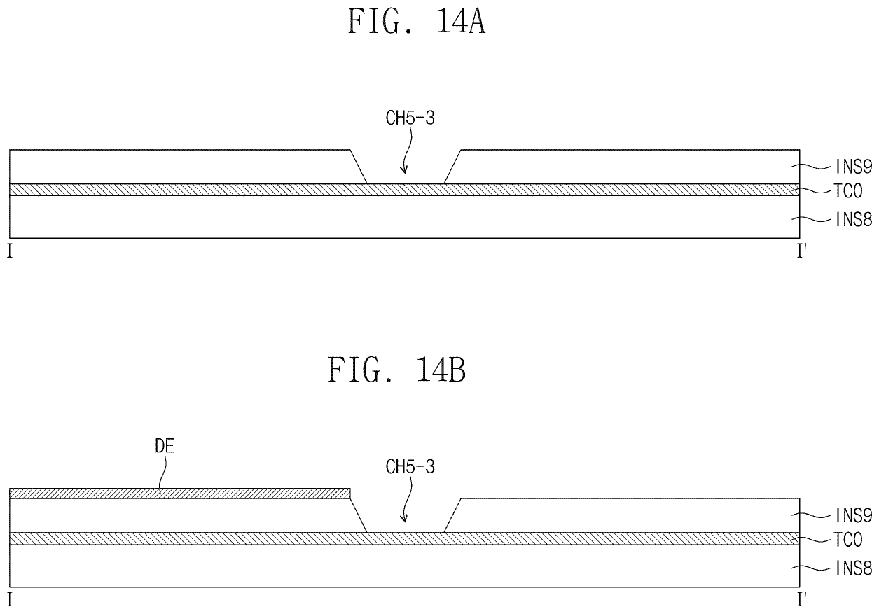

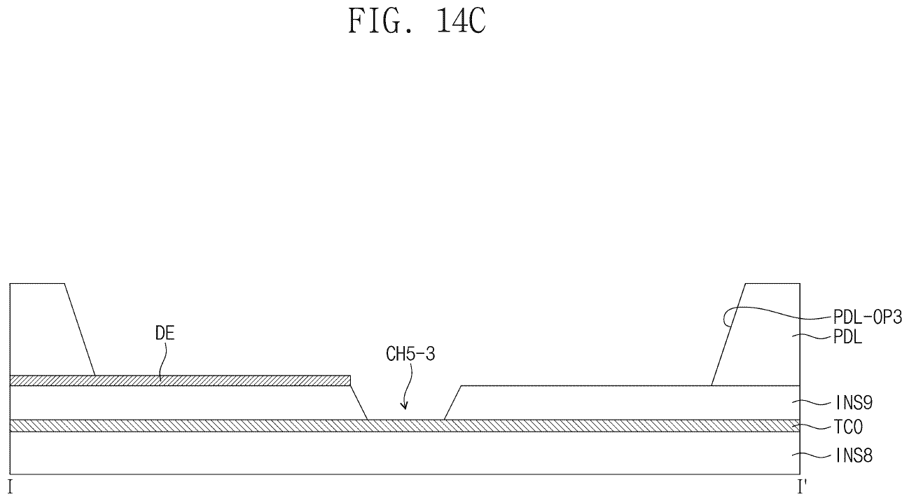

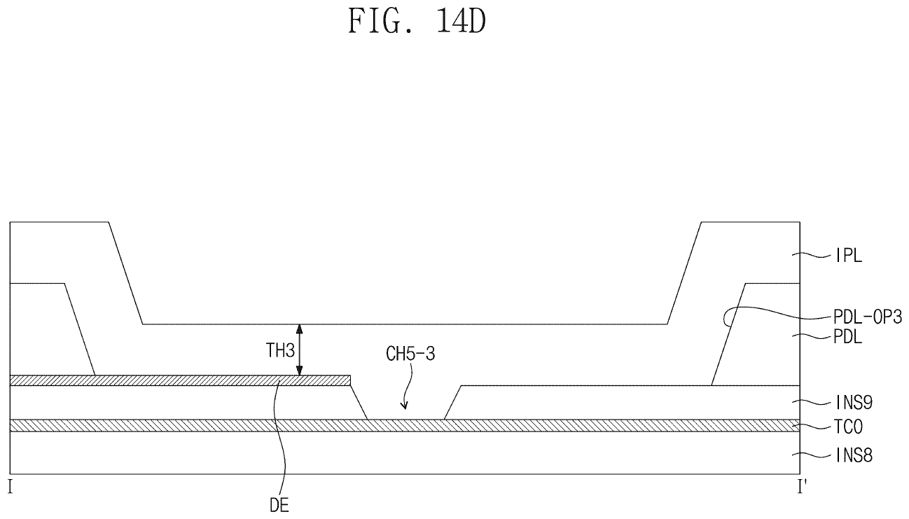

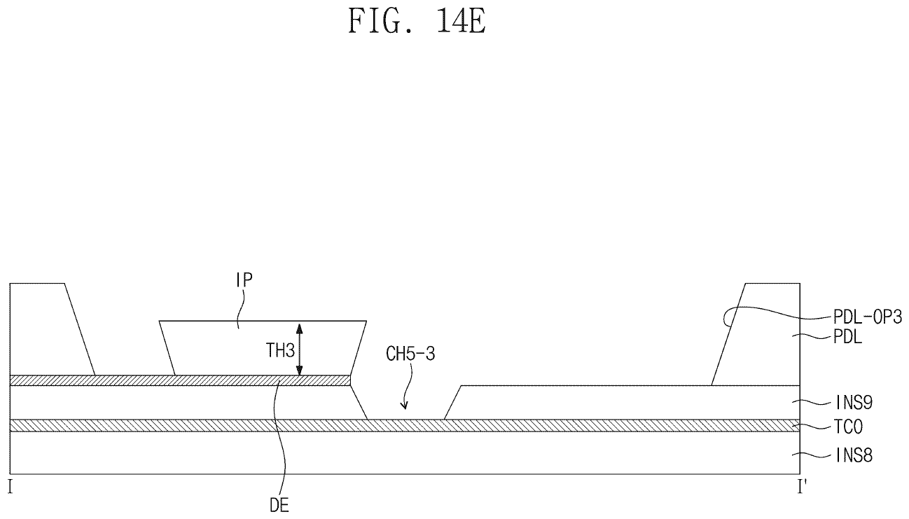

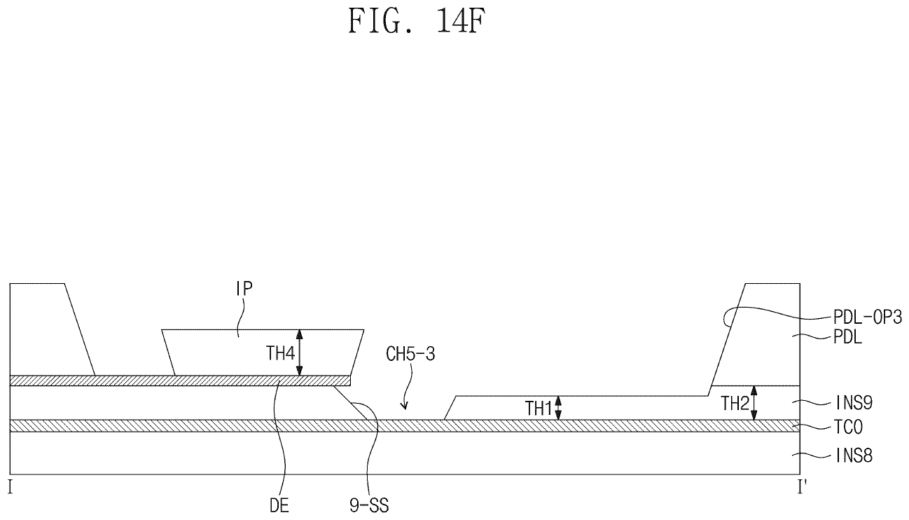

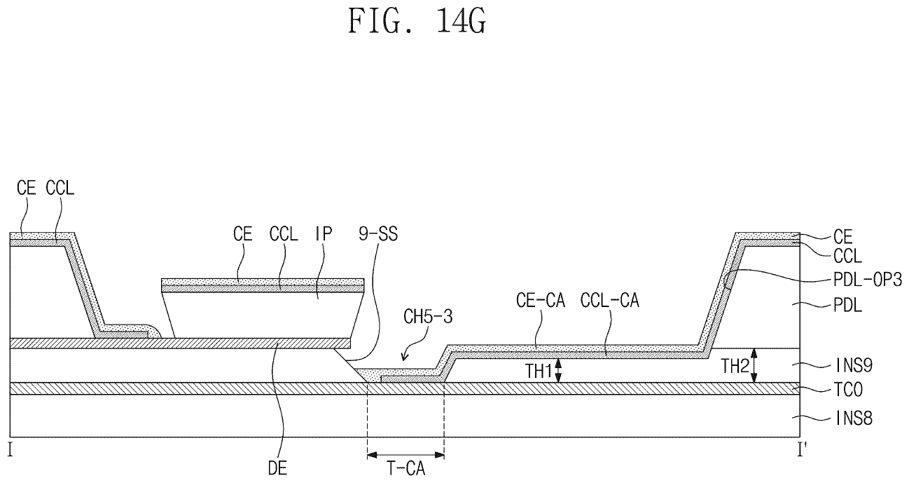

FIG. 13 is a sectional view of the display panel DP corresponding to line I-I′ in FIG. 12M. FIGS. 14A to 14G are sectional views illustrating a process of manufacturing the display panel DP.

In FIGS. 13 and 14A to 14G, the components disposed under the eighth insulating layer INS8 illustrated in FIGS. 6 and 7 are not illustrated. The manufacturing process in FIGS. 14A to 14G corresponds to the process in FIG. 12K and the subsequent process. Hereinafter, detailed descriptions of the components described with reference to FIGS. 12K to 12M refer to the corresponding descriptions, and repetitive descriptions will be omitted.

Referring to FIG. 13, an organic layer CCL and the common electrode CE are additionally illustrated. The fifth contact hole CH5-3 is defined in the ninth insulating layer INS9. The contact area T-CA in which the common electrode CE contacts the shielding electrode TCO is exposed through the fifth contact hole CH5-3.

The dummy electrode DE is disposed on the ninth insulating layer INS9. A portion of the dummy electrode DE overlaps a partial area of the fifth contact hole CH5-3 when viewed from above the plane. The insulating pattern IP is disposed on a portion of the dummy electrode DE. A portion of the insulating pattern IP overlaps a partial area of the fifth contact hole CH5-3 when viewed from above the plane. A portion of the inner surface 9-SS of the ninth insulating layer INS9 defines the fifth contact hole CH5-3. A portion of the dummy electrode DE overlapping the contact hole CH5-3 is spaced apart from a portion of the inner surface 9-SS of the ninth insulating layer INS9 in a plan view.

The pixel defining layer PDL is disposed on the ninth insulating layer INS9. The third opening PDL-OP3 exposing the fifth contact hole CH5-3 is defined in the pixel defining layer PDL. The fifth contact hole CH5-3 is disposed in the third opening PDL-OP3 when viewed from above the plane. The third opening PDL-OP3 exposes a portion of the dummy electrode DE. The insulating pattern IP may be disposed in the third opening PDL-OP3 and may be spaced apart from the pixel defining layer PDL.

In the process of forming the insulating pattern IP, the ninth insulating layer INS9 may also be additionally etched, and the ninth insulating layer INS9 disposed under the dummy electrode DE may also be removed in the corresponding etching process. Accordingly, the dummy electrode DE and the insulating pattern IP may form a tip structure. The tip structure functions as a shielding structure in a depositing process of the organic layer and the common electrode that will be described below.

The insulating pattern IP may have an inverted taper structure. That is, the side surface of the insulating pattern IP may define an obtuse angle with respect to the lower surface of the insulating pattern IP. The insulating pattern IP may have a shape having an increasing width from bottom to top. The insulating pattern IP having the inverted taper structure may be more suitable for the above-described shielding function. Detailed description thereabout will be given below.

In addition, in the corresponding etching process, the thickness of a portion of the ninth insulating layer INS9 which is not covered by the pixel defining layer PDL and/or the dummy electrode DE may be decreased. The thickness TH1 (hereinafter, referred to as the first thickness) of a portion of the ninth insulating layer INS9 that is not covered by the pixel defining layer PDL and/or the dummy electrode DE (or, a portion of the ninth insulating layer INS9 exposed from the third opening PDL-OP3) may be smaller than the thickness TH2 (hereinafter, referred to as the second thickness) of a portion of the ninth insulating layer INS9 that is covered by the pixel defining layer PDL and/or the dummy electrode DE.

The organic layer CCL may be disposed on the pixel defining layer PDL and the insulating pattern IP. The organic layer CCL may make contact with the upper surface of the pixel defining layer PDL and the upper surface of the insulating pattern IP. The organic layer CCL may include the hole control layer HCL of FIGS. 6 and 7 and the electron control layer ECL of FIGS. 6 and 7 disposed over the hole control layer HCL. The organic layer CCL may be deposited through an open mask to have a one-body shape over the entire display panel DP.

The organic layer CCL may overlap the emissive layer EML of FIG. 6 and the photoelectric conversion layer OPD of FIG. 7. The emissive layer EML may be disposed between the hole control layer HCL and the electron control layer ECL to correspond to the emissive area LEA of FIG. 6, and the photoelectric conversion layer OPD may be disposed between the hole control layer HCL′ and the electron control layer ECL′ to correspond to the light receiving area LRA of FIG. 7.

Hereinafter, an area or a portion of the organic layer CCL disposed in the third opening PDL-OP3 in the contact area T-CA is defined as an organic layer contact area CCL-CA or an organic layer contact portion CCL-CA. The organic layer contact area CCL-CA of the organic layer CCL overlaps the fifth contact hole CH5-3. The organic layer contact area CCL-CA of the organic layer CCL may not overlap a partial area of the contact area T-CA of the shielding electrode TCO.

The common electrode CE is disposed on the organic layer CCL. An area of the common electrode CE disposed in the third opening PDL-OP3 in the contact area T-CA is defined as a contact area common electrode CE-CA. The contact area common electrode CE-CA of the common electrode CE overlaps the fifth contact hole CH5-3. The contact area common electrode CE-CA of the common electrode CE may overlap the organic layer contact area CCL-CA of the organic layer CCL. The contact area common electrode CE-CA of the common electrode CE may make contact with a partial area of the contact area T-CA of the shielding electrode TCO that the organic layer contact area CCL-CA of the organic layer CCL does not cover. Accordingly, the common electrode CE and the shielding electrode TCO may be electrically connected with each other.

As described with reference to FIG. 12K, the shielding electrode TCO has a certain shape in the display area DA and is disposed over the entire display area DA. The contact area CA described with reference to FIGS. 12M and 13 may also be disposed over the entire display area DA. Accordingly, the shielding electrode TCO may serve as an auxiliary electrode that prevents a voltage drop of the common electrode CE. The second driving voltage ELVSS may be transferred from the shielding electrode TCO to the common electrode CE through the plurality of contact areas CA in the display area DA.

Hereinafter, the manufacturing process of the display panel DP will be described with reference to FIGS. 14A to 14G.

As illustrated in FIG. 14A, the ninth insulating layer INS9 that covers the shielding electrode TCO and in which the fifth contact hole CH5-3 is defined is formed on the eighth insulating layer INS8. The ninth insulating layer INS9 may be formed using a photolithography process. An inorganic layer may be formed using a deposition process, or an organic layer may be formed through a coating process or an ink-jet process. The fifth contact hole CH5-3 may be formed in the organic layer using positive photoresist.

As illustrated in FIG. 14B, the dummy electrode DE is formed on the ninth insulating layer INS9. The dummy electrode DE may be formed using a photolithography process. The edge of the dummy electrode DE may be aligned with the edge of the fifth contact hole CH5-3. A transparent conductive oxide layer may be formed on the ninth insulating layer INS9 through a deposition process. The transparent conductive oxide layer may be subjected to patterning using negative photoresist.

As illustrated in FIG. 14C, the pixel defining layer PDL having the third opening PDL-OP3 defined therein is formed on the ninth insulating layer INS9. The pixel defining layer PDL may be formed using a photolithography process. An organic layer may be formed through a coating process or an ink-jet process. The third opening

PDL-OP3 may be formed in the organic layer using positive photoresist. Although not illustrated, the first opening PDL-OP1 of FIG. 6 and the second opening PDL-OP2 of FIG. 7 may also be simultaneously formed together with the third opening PDL-OP3.

As illustrated in FIGS. 14D and 14E, the insulating pattern IP is formed in the third opening PDL-OP3. As illustrated in FIG. 14D, an organic layer IPL is formed on the ninth insulating layer INS9 and the pixel defining layer PDL. The organic layer IPL may be formed through a coating process or an ink-jet process. As illustrated in FIG. 14E, a negative photoresist layer is formed on the organic layer IPL, and thereafter the insulating pattern IP is formed from the organic layer IPL through exposure, developing, and etching processes. The insulating pattern IP has the same thickness TH3 (hereinafter, referred to as the third thickness) as the organic layer IPL.

As illustrated in FIG. 14F, an etching process is additionally performed. Isotropic etching may be performed using the pixel defining layer PDL and the insulating pattern IP as a mask. The thickness of the insulating pattern IP is decreased from the third thickness TH3 of FIG. 14D to the fourth thickness TH4. A partial area of the ninth insulating layer INS9 exposed from the pixel defining layer PDL may be etched, and the thickness of the partial area of the ninth insulating layer INS9 may decrease. As described with reference to FIG. 13, an area having the first thickness TH1 is formed in the ninth insulating layer INS9.

Although the area of the ninth insulating layer INP9 covered by the dummy electrode DE is not etched, the inner surface 9-SS of the fifth contact hole CH5-3 is etched in the horizontal direction, and thus the area of the fifth contact hole CH5-3 is increased. Accordingly, a partial area of the inner surface 9-SS is disposed under the dummy electrode DE.

As illustrated in FIG. 14G, the organic layer CCL and the common electrode CE are sequentially deposited. The material constituting the organic layer CCL is deposited more vertically than the material constituting the common electrode CE. Since the tip structure of the dummy electrode DE and the insulating pattern IP serves as a shielding structure when the organic layer CCL is deposited, the organic layer CCL fails to completely cover the contact area T-CA of the shielding electrode TCO.

The material constituting the common electrode CE is deposited more obliquely than the material constituting the organic layer CCL. Accordingly, the common electrode CE may be deposited to an area of the organic layer CCL exposed from the contact area T-CA of the shielding electrode TCO. Thus, the common electrode CE may be electrically connected to the contact area T-CA of the shielding electrode TCO.

According to the embodiments of the present disclosure, the shielding electrode, to which a constant voltage is applied, may be disposed between the readout line and the light emitting element or between the readout line and the light sensing element. Accordingly, the signal-to-noise ratio of the sensing signal output through the readout line may be improved. Thus, the sensitivity of the light sensor may be improved.

The shielding electrode that receives the low driving voltage ELVSS may serve as an auxiliary electrode. The shielding electrode may be connected to the common electrode through the plurality of points, and thus the voltage drop occurring in the common electrode may be reduced.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a base layer;
a readout line disposed on the base layer;
a first insulating layer disposed on the readout line;
a shielding electrode disposed on the first insulating layer and overlapping the readout line;
a second insulating layer disposed on the first insulating layer and overlapping the shielding electrode, the second insulating layer having a contact hole defined therein to expose a contact portion of the shielding electrode;
a light emitting element disposed on the second insulating layer, the light emitting element including a first electrode, a second electrode disposed over the first electrode, and an emissive layer disposed between the first electrode and the second electrode;
a light sensing element disposed on the second insulating layer, the light sensing element including a first-first electrode, a second-first electrode disposed over the first-first electrode, and a photoelectric conversion layer disposed between the first-first electrode and the second-first electrode;
a pixel defining layer disposed on the second insulating layer, the pixel defining layer having a first opening, a second opening, and a third opening defined therein, wherein the first opening exposes the first electrode, the second opening exposes the first-first electrode, and the third opening exposes the contact hole;
a dummy electrode disposed on the second insulating layer and overlapping a partial area of the contact hole; and
an insulating pattern disposed in the third opening and overlapping the dummy electrode,
wherein the second electrode and the second-first electrode are different portions of a common electrode, and
a contact portion of the common electrode connecting the common electrode to the contact portion of the shielding electrode is disposed in the contact hole.

2. The display device of claim 1, wherein an inner surface of the second insulating layer defines the contact hole, and
a portion of the dummy electrode overlapping the contact hole is spaced apart from a portion of the inner surface of the second insulating layer.

3. The display device of claim 1, further comprising:
an organic layer disposed under the common electrode,
wherein a contact portion of the organic layer is disposed in the contact hole, and
wherein the contact portion of the organic layer does not completely cover the shielding electrode exposed by the contact hole.

4. The display device of claim 3, wherein the organic layer overlaps the emissive layer, the photoelectric conversion layer, and an upper surface of the pixel defining layer.

5. The display device of claim 1, further comprising:
a signal line disposed under the first insulating layer and configured to receive a same driving voltage as the second electrode,
wherein the shielding electrode is electrically connected to the signal line.

6. The display device of claim 5, wherein the signal line extends in a first direction, and
wherein the shielding electrode includes a first extending portion extending in the first direction and second extending portions extending from the first extending portion in a second direction crossing the first direction.

7. The display device of claim 1, wherein the shielding electrode includes transparent conductive oxide.

8. The display device of claim 1, wherein the dummy electrode includes a same material as the first electrode.

9. The display device of claim 1, wherein the shielding electrode and the readout line overlap the first electrode in a plane view.

10. The display device of claim 1, wherein a portion of the second insulating layer in the third opening has a smaller thickness than a portion of the second insulating layer overlapping the pixel defining layer.

11. The display device of claim 1, further comprising:
a first driving circuit disposed on the base layer and configured to control the light emitting element; and
a second driving circuit disposed on the base layer and electrically connected to the light sensing element,
wherein the readout line is electrically connected to the second driving circuit.

12. The display device of claim 1, wherein the readout line includes a first portion and a second portion disposed on different layers.

13. The display device of claim 1, wherein the third opening has a larger area than the contact hole in a plane view.

14. A display device comprising:
a base layer;
a driving circuit disposed on the base layer;
a readout line disposed on the base layer and electrically connected to the driving circuit;
a first insulating layer disposed on the readout line;
a shielding electrode disposed on the first insulating layer and overlapping the readout line;
a second insulating layer disposed on the first insulating layer and overlapping the shielding electrode, the second insulating layer having a contact hole defined therein to expose a contact portion of the shielding electrode;
a light sensing element disposed on the second insulating layer, the light sensing element including a first-first electrode, a second-first electrode disposed over the first-first electrode, and a photoelectric conversion layer disposed between the first-first electrode and the second-first electrode;
a pixel defining layer disposed on the second insulating layer, the pixel defining layer having a first opening and a second opening defined therein, wherein the first opening exposes the first-first electrode and the second opening exposes the contact hole; and
a dummy electrode disposed between the second insulating layer and the pixel defining layer and overlapping a partial area of the contact hole,
wherein the second-first electrode is disposed on an upper surface of the pixel defining layer, and
a contact portion of the second-first electrode connecting the second-first electrode to the contact portion of the shielding electrode is disposed in the contact hole.

15. The display device of claim 14, an inner surface of the second insulating layer defines the contact hole, and
a portion of the dummy electrode overlapping the contact hole is spaced apart from a portion of the inner surface of the second insulating layer.

16. The display device of claim 14, further comprising:
an organic layer disposed under the second-first electrode and overlapping the upper surface of the pixel defining layer,
wherein a contact portion of the organic layer is disposed in the contact hole, and
wherein the contact portion of the organic layer does not completely cover the contact area exposed by the contact hole.

17. The display device of claim 14, further comprising:
a signal line disposed under the first insulating layer and configured to receive a same driving voltage as the second electrode,
wherein the shielding electrode is electrically connected to the signal line.

18. The display device of claim 14, wherein the shielding electrode includes transparent conductive oxide.

19. The display device of claim 14, wherein the dummy electrode includes a same material as the first-first electrode.

20. The display device of claim 14, wherein a portion of the second insulating layer in the second opening has a smaller thickness than a portion of the second insulating layer overlapping the pixel defining layer.

21. An electronic device comprising:
a display device; and
a housing accommodating the display device,
wherein the display device includes:
a base layer;
a readout line disposed on the base layer;
a first insulating layer disposed on the readout line;
a shielding electrode disposed on the first insulating layer and overlapping the readout line;
a second insulating layer disposed on the first insulating layer and overlapping the shielding electrode, the second insulating layer having a contact hole defined therein to expose a contact portion of the shielding electrode;
a light emitting element disposed on the second insulating layer, the light emitting element including a first electrode, a second electrode disposed over the first electrode, and an emissive layer disposed between the first electrode and the second electrode;
a light sensing element disposed on the second insulating layer, the light sensing element including a first-first electrode, a second-first electrode disposed over the first-first electrode, and a photoelectric conversion layer disposed between the first-first electrode and the second-first electrode;
a pixel defining layer disposed on the second insulating layer, the pixel defining layer having a first opening, a second opening, and a third opening defined therein, wherein the first opening exposes the first electrode, the second opening exposes the first-first electrode, and the third opening exposes the contact hole;
a dummy electrode disposed on the second insulating layer and overlapping a partial area of the contact hole; and
an insulating pattern disposed in the third opening and overlapping the dummy electrode,
wherein the second electrode and the second-first electrode are different portions of a common electrode, and
a contact portion of the common electrode connecting the common electrode to the contact portion of the shielding electrode is disposed in the contact hole.

22. The electronic device of claim 1, wherein an inner surface of the second insulating layer defines the contact hole, and
a portion of the dummy electrode overlapping the contact hole is spaced apart from a portion of the inner surface of the second insulating layer.

23. The electronic device of claim 1, further comprising:
an organic layer disposed under the common electrode,
wherein a contact portion of the organic layer is disposed in the contact hole, and
wherein the contact portion of the organic layer does not completely cover the shielding electrode exposed by the contact hole.

24. The electronic device of claim 3, wherein the organic layer overlaps the emissive layer, the photoelectric conversion layer, and an upper surface of the pixel defining layer.

25. The electronic device of claim 1, wherein the electronic device is one of a smartphone, a tablet PC, a laptop, a TV, and a desk monitor.
